(19) United States
(12) Patent Application Publication
(10) Pub. No.: US 2008/0179687 A1
(43) Pub. Date: Jul. 31, 2008

(54) SEMICONDUCTOR DEVICE AND METHOD FOR MANUFACTURING THE SAME

(76) Inventor: Yoshihiro SATO, Hyogo (JP)

Correspondence Address: MCDERMOTT WILL & EMERY LLP, 600 13TH STREET, NW, WASHINGTON, DC, 20005-3096, US

(21) Appl. No.: 11/950,829

(22) Filed: Dec. 5, 2007

(30) Foreign Application Priority Data
Jan. 31, 2007 (JP) 2007-021864

(51) Int. Cl. H01L 27/092; H01L 21/04

(52) U.S. Cl. 257/369; 438/154; 257/E27.062; 257/E21.04

(57) ABSTRACT

A semiconductor device, wherein: the first MIS transistor includes a first fully-silicided gate electrode formed on a first gate insulating film and made of a first metal silicide film; and the second MIS transistor includes a second fully-silicided gate electrode formed on a second gate insulating film and made of a second metal silicide film whose silicide composition is different from that of the first metal silicide film. The semiconductor device further includes an L-shaped insulating film, the L-shaped insulating film being integral with the second gate insulating film and extending from a top of an isolation region formed between a first active region and a second active region of a semiconductor substrate along a side surface of the second fully-silicided gate electrode in a gate width direction; and the first fully-silicided gate electrode and the second fully-silicided gate electrode are electrically connected with each other.

### CROSS REFERENCE TO RELATED APPLICATION

This application claims priority under 35 U.S.C. §119 on Patent Application No. 2007-021864 filed in Japan on Jan. 31, 2007, the entire contents of which are hereby incorporated by reference.

### BACKGROUND OF THE INVENTION

The present invention relates to a method for manufacturing a semiconductor device, and more particularly to a semiconductor device having a fully-silicided gate electrode and a method for manufacturing the same.

In recent years, demands for miniaturizing MOSFETs have been increasing along with the increase in the degree of integration and the speed of semiconductor integrated circuit devices, and techniques for metallizing gate electrodes have been actively researched in order to solve problems, such as the depletion capacitance of the polysilicon gate electrode becoming pronounced due to the thickness of the gate insulating film becoming very small, and the penetration of boron into channel regions. Particularly, full silicidation (FUSI) techniques, where the entire gate electrode is made into a metal silicide film, are attracting attention as being promising because they can be implemented based on the current silicon process techniques.

A FUSI gate electrode can be formed by forming a polysilicon film having a gate pattern shape and allowing the polysilicon film to react with a metal film made of a metal such as nickel, as with the formation of an ordinary polysilicon gate electrode.

However, simply substituting a polysilicon gate electrode with a FUSI gate electrode leaves a problem that it is difficult to realize an intended threshold voltage for each of the n-type MIS transistor and the p-type MIS transistor.

In order to solve this problem, it has been proposed in the art to change the silicide composition ratio of the FUSI gate electrode depending on the conductivity type of the MIS transistor (see, for example, Non-Patent Document 1: J. A. Kittl, et al., “Scalability of Ni FUSI gate processes: phase and Vt control to 30 nm gate lengths”, VLSI2005, and Non-Patent Document 2: A. Lauwers, et al., “CMOS Integration of Dual Work Function Phase Controlled Ni FUSI with Simultaneous Silicidation of NMOS (NiSi) and PMOS (Ni-rich silicide) Gates on HfSiON”, IEDM2005). Since the work function of a metal silicide film changes according to the silicide composition ratio thereof, it is possible to adjust the work function of the FUSI gate electrode to an intended work function by setting the silicide composition ratio thereof to an intended ratio. Thus, it is possible to control the threshold voltage of the MIS transistor.

The silicide composition ratio of the FUSI gate electrode is determined by the thickness ratio between the polysilicon film thickness and the metal film thickness in the FUSI step. A conventional method for manufacturing a semiconductor device will now be described briefly with reference to FIGS. 13A to 13D. FIGS. 13A to 13D are cross-sectional views taken in the gate length direction, sequentially showing important steps of a conventional method for manufacturing a semiconductor device. Particularly, FIGS. 13A to 13D are cross-sectional views showing important steps, including a pre-FUSI step and the FUSI step. The N-type MIS-forming region and the P-type MIS-forming region are shown in these figures as being adjacent to each other for the sake of simplicity. The designation “N” in the left half of the figures denotes the N-type MIS-forming region, and the designation “P” in the right half of the figures denotes the P-type MIS-forming region. Moreover, extension regions, source-drain regions, etc., are also not shown in the figures for the sake of simplicity.

Steps similar to those of a method for manufacturing a semiconductor device having an ordinary polysilicon gate electrode are performed to form a gate electrode-forming film 304a made of a polysilicon film on an active region 300a in the N-type MIS-forming region, which is a portion of a p-type well region 302a that is delimited by an isolation region 301, with a gate insulating film 303a being interposed therebetween, and a gate electrode-forming film 304b made of a polysilicon film on an active region 300b in the P-type MIS-forming region, which is a portion of an n-type well region 302b that is delimited by the isolation region 301, with a gate insulating film 303b being interposed therebetween, as shown in FIG. 13A. The gate electrode-forming film 304a in the N-type MIS-forming region and the gate electrode-forming film 304b in the P-type MIS-forming region have the same thickness. Then, side walls 305a and 305b are formed on the side surfaces of the gate electrode-forming films 304a and 304b, respectively. Then, after an interlayer insulating film 308 is formed across the entire surface of a semiconductor substrate 300, the surface of the interlayer insulating film 308 is flattened and etched so that the upper surface of the gate electrode-forming films 304a and 304b is exposed.

Then, the gate electrode-forming film 304b in the P-type MIS-forming region is etched as shown in FIG. 13B, whereby the thickness of the gate electrode-forming film 304b in the P-type MIS-forming region (“P_{Si}” in FIG. 13B) is smaller than the thickness of the gate electrode-forming film 304a in the N-type MIS-forming region (“N_{Si}” in FIG. 13B).

Then, a metal film 306 of nickel is formed across the entire surface of the semiconductor substrate 300 so as to cover the gate electrode-forming films 304a and 304b, as shown in FIG. 13C.

Thus, the thickness of the metal film 306 with respect to the thickness of the gate electrode-forming film 304a in the N-type MIS-forming region, i.e., the ratio Ni/Si of nickel with respect to silicon in the N-type MIS-forming region (see the metal film thickness N_{Ni} and the polysilicon film thickness N_{Si} in FIG. 13C) is set to be smaller than the ratio Ni/Si of nickel with respect to silicon in the P-type MIS-forming region (see the metal film thickness P_{Ni} and the polysilicon film thickness P_{Si} in FIG. 13C). In other words, with respect to the thickness ratio between the polysilicon film thickness and the metal film thickness, the proportion of the thickness of Ni in the N-type MIS-forming region is set to be smaller than that in the P-type MIS-forming region.

Then, a heat treatment is performed so that nickel of the metal film 306 is allowed to react with silicon of the gate electrode-forming film 304a in the N-type MIS-forming region and the gate electrode-forming film 304b in the P-type MIS-forming region, thereby making these portions into metal silicide portions, as shown in FIG. 13D. Then, unreacted portions of the metal film 306 remaining on the semiconductor substrate 300 are etched away.

Thus, in the N-type MIS-forming region, the entirety of the gate electrode-forming film 304a is allowed to react with the metal film 306 to thereby form a FUSI gate electrode 307a made of a metal silicide film having a silicide composition ratio according to the thickness ratio between the polysilicon film thickness N_{Si} and the metal film thickness N_{Ni} in the FUSI step, whereas in the P-type MIS-forming region, the entirety of the gate electrode-forming film 304b is allowed to react with the metal film 306 to thereby form a FUSI gate electrode 307b made of a metal silicide film having a silicide composition ratio according to the thickness ratio between the polysilicon film thickness P_{Si} and the metal film thickness P_{Ni} in the FUSI step.

With the conventional method for manufacturing a semiconductor device, the polysilicon film thickness of the gate electrode-forming film in the P-type MIS-forming region is adjusted by means of etching. In order to adjust the polysilicon film thickness with a high precision by means of etching, it is necessary to control the etching conditions, particularly the etching rate and the etching time, with a high precision.

However, it is very difficult to control the etching rate with a high precision as will be described below, and the conventional method for manufacturing a semiconductor device therefore has the following problem.

For example, it is very difficult to evenly control the chamber temperature (in other words, the etching temperature) between different lots, and therefore the etching rate varies between different lots. Even within the same lot, it is very difficult to evenly control the chamber temperature while different wafers are successively etched, and therefore the etching rate also varies within the same lot. Thus, with the conventional method for manufacturing a semiconductor device, the polysilicon film thickness of the gate electrode-forming film in the P-type MIS-forming region varies substantially between wafers due to variations in the etching rage between different lots and variations in the etching rate within the same lot.

Moreover, even within the same wafer, the etching rate varies between a polysilicon film having a larger area to be etched and a polysilicon film having a smaller area to be etched, due to the microloading effect. Therefore, with the conventional method for manufacturing a semiconductor device, the polysilicon film thickness of the gate electrode-forming film in the P-type MIS-forming region varies even within the same wafer because the etching rate varies due to a difference in the area to be etched.

Thus, with the conventional method for manufacturing a semiconductor device, the polysilicon film thickness varies between different wafers and the polysilicon film thickness also varies within the same wafer, whereby the polysilicon film thickness varies between gate electrode-forming films of different P-type MIS-forming regions, and the ratio between the polysilicon film thickness and the metal film thickness varies therebetween.

Furthermore, even within a gate electrode-forming film of the same P-type MIS-forming region, the etching rate varies between an edge portion and a central portion of the polysilicon film surface. Therefore, with the conventional method for manufacturing a semiconductor device, the polysilicon film thickness varies even within a gate electrode-forming film of the same P-type MIS-forming region due to the difference in the etching rate between the edge portion and the central portion. Thus, the polysilicon film surface becomes rough, and the ratio between the polysilicon film thickness and the metal film thickness varies (in other words, the thickness ratio in the edge portion differs from that in the central portion).

Thus, with the conventional method for manufacturing a semiconductor device, the silicide composition ratio of the metal silicide film varies between different p-type MIS transistors, due to variations in the thickness ratio between gate electrode-forming films of different P-type MIS-forming regions. In addition, due to the variations in the thickness ratio within a gate electrode-forming film of the same P-type MIS-forming region, the silicide composition ratio of the metal silicide film varies even within the same p-type MIS transistor (in other words, the silicide ratio in the edge portion differs from that in the central portion).

Therefore, with the conventional method for manufacturing a semiconductor device, it is possible to obtain, in an n-type MIS transistor, a FUSI gate electrode made of a metal silicide film of an intended silicide composition ratio, but it is not possible to obtain, in a p-type MIS transistor (i.e., in a MIS transistor whose polysilicon film thickness has been adjusted by etching, a FUSI gate electrode made of a metal silicide film of an intended silicide composition ratio. Thus, it is not possible to obtain a FUSI gate electrode made of a metal silicide film of an intended silicide composition ratio both in the n-type MIS transistor and in the p-type MIS transistor.

Thus, with the conventional method for manufacturing a semiconductor device, it is possible to control the threshold voltage of the n-type MIS transistor to an intended threshold voltage, but it is not possible to control the threshold voltage of the p-type MIS transistor to an intended threshold voltage. Therefore, it is not possible to obtain an intended threshold voltage both in the n-type MIS transistor and in the p-type MIS transistor.

### SUMMARY OF THE INVENTION

In view of the above, it is an object of the present invention to realize a fully-silicided gate electrode made of a metal silicide film having an intended silicide composition ratio with a high precision both in a p-type MIS transistor and in an n-type MIS transistor by adjusting the thickness of each of a gate electrode-forming film in a P-type MIS-forming region and a gate electrode-forming film in an N-type MIS-forming region to an intended thickness with a high precision.

In order to achieve the object set forth above, a semiconductor device according to one aspect of the present invention is a semiconductor device, including a first MIS transistor of a first conductivity type and a second MIS transistor of a second conductivity type, wherein: the first MIS transistor includes: a first gate insulating film formed in a first active region on a semiconductor substrate; a first fully-silicided gate electrode formed on the first gate insulating film and made of a first metal silicide film; and a first side wall formed on a side surface of the first fully-silicided gate electrode; and the second MIS transistor includes: a second gate insulating film in a second active region on the semiconductor substrate; a second fully-silicided gate electrode formed on the second gate insulating film and made of a second metal silicide film whose silicide composition is different from that of the first metal silicide film; and a second side wall formed on a side surface of the second fully-silicided gate electrode, wherein: the semiconductor device further includes an L-shaped insulating film having an L-shaped cross section, the L-shaped insulating film being integral with the second gate insulating film and extending from a top of an isolation region formed between the first active region and the second active region of the semiconductor substrate along a side surface of the second fully-silicided gate electrode in a gate width direction; and the first fully-silicided gate electrode and the second fully-silicided gate electrode are electrically connected with each other.

The semiconductor device according to one aspect of the present invention does not use an MIS transistor whose thickness is adjusted by means of etching as with conventional methods as a p-type MIS transistor or an n-type MIS transistor. Therefore, it is possible to realize with a high precision a fully-silicided gate electrode made of a metal silicide film of an intended silicide composition ratio both for the p-type MIS transistor and for the n-type MIS transistor, whereby it is possible to realize an intended threshold voltage with a high precision.

In the semiconductor device according to one aspect of the present invention, it is preferred that an upper surface of the L-shaped insulating film is lower than that of the first fully-silicided gate electrode and that of the second fully-silicided gate electrode; and the first fully-silicided gate electrode and the second fully-silicided gate electrode are in contact with each other above the L-shaped insulating film.

Then, as the first fully-silicided gate electrode and the second fully-silicided gate electrode are in contact with each other, it is possible to ensure the electrical connection therebetween.

In the semiconductor device according to one aspect of the present invention, it is preferred that the semiconductor device further includes a contact plug formed on the first fully-silicided gate electrode and the second fully-silicided gate electrode so as to extend across the L-shaped insulating film, the contact plug electrically connecting the first fully-silicided gate electrode and the second fully-silicided gate electrode with each other.

Then, with the contact plug, it is possible to reliably ensure the electrical connection between the first fully-silicided gate electrode and the second fully-silicided gate electrode.

In the semiconductor device according to one aspect of the present invention, it is preferred that the first MIS transistor further includes: a first extension region formed in a portion of the first active region which is under the side of the first fully-silicided gate electrode; and a first source-drain region formed in a portion of the first active region which is under the side of the first side wall; and the second MIS transistor further includes: a second extension region formed in a portion of the second active region which is under the side of the second fully-silicided gate electrode; and a second source-drain region formed in a portion of the second active region which is under the side of the second side wall.

In the semiconductor device according to one aspect of the present invention, it is preferred that the first MIS transistor further includes a first silicide film formed in an upper portion of the first source-drain region; and the second MIS transistor further includes a second silicide film formed in an upper portion of the second source-drain region.

In the semiconductor device according to one aspect of the present invention, it is preferred that a height of an upper surface of the first fully-silicided gate electrode is different from that of an upper surface of the second fully-silicided gate electrode.

In the semiconductor device according to one aspect of the present invention, it is preferred that the first metal silicide film is made of Ni₃₁Si₁₂, Ni₃Si or Ni₂Si; and the second metal silicide film is made of NiSi.

In the semiconductor device according to one aspect of the present invention, it is preferred that the first metal silicide film is made of Ni₂(SiGe) or Ni₃(SiGe)₂; and the second metal silicide film is made of NiSi.

In the semiconductor device according to one aspect of the present invention, it is preferred that the first MIS transistor is a p-type MIS transistor; and the second MIS transistor is an n-type MIS transistor.

In the semiconductor device according to one aspect of the present invention, it is preferred that the first gate insulating film and the second gate insulating film include a high-k film whose relative dielectric constant is 10 or higher. For example, it is preferred that the first gate insulating film and the second gate insulating film include a metal oxide. Specifically, it is preferred that the first gate insulating film and the second gate insulating film include at least one oxide selected from the group consisting of a hafnium (Hf)-containing oxide, a tantalum (Ta)-containing oxide, a lanthanum (La)-containing oxide and an aluminum (Al)-containing oxide.

Then, the Fermi level pinning is eased, thereby improving the controllability of the threshold voltage for the n-type MIS transistor and for the p-type MIS transistor.

In order to achieve the object set forth above, a method for manufacturing a semiconductor device according to one aspect of the present invention is a method for manufacturing a semiconductor device including a first MIS transistor of a first conductivity type and a second MIS transistor of a second conductivity type, the method including: a step (a) of forming a first active region and a second active region in a semiconductor substrate, the first active region and the second active region being isolated from each other by an isolation region; a step (b) of successively forming a first insulating film and a first silicon film having a first thickness on the first active region; a step (c), after the step (b), of successively forming a second insulating film and a second silicon film having a second thickness larger than the first thickness across the entire surface of the semiconductor substrate; a step (d), after the step (c), of patterning the second silicon film, the second insulating film, the first silicon film and the first insulating film to thereby form on the first active region a first gate electrode pattern including a first gate insulating film made of the first insulating film and a first gate electrode-forming film made of the first silicon film, and patterning the second silicon film and the second insulating film to thereby form on the second active region a second gate electrode pattern including a second gate insulating film made of the second insulating film and a second gate electrode-forming film made of the second silicon film; a step (e) of forming a first side wall on a side surface of the first gate electrode pattern and forming a second side wall on a side surface of the second gate electrode pattern; a step (f), after the step (e), of successively removing the second silicon film and the second insulating film of the first gate electrode pattern to thereby expose the first gate electrode-forming film of the first gate electrode pattern; a step (g), after the step (f), of forming a metal film on the first gate electrode-forming film of the first gate electrode pattern and the second gate electrode-forming film of the second gate electrode pattern; and a step (h) of performing a heat treatment to allow an entirety of the first gate electrode-forming film of the first gate electrode pattern to react with the metal film so as to form a first fully-silicided gate electrode made of a first metal silicide film, and allow an entirety of the second gate electrode-forming film of the second gate electrode pattern to react with the metal film so as to form a second fully-silicided gate electrode made of a second metal silicide film having a silicide composition different from that of the first metal silicide film, wherein: the step (c) includes a step of forming an L-shaped insulating film-forming film made of the second insulating film on the isolation region and on a side surface of the second silicon film; the step (d) includes a step of patterning the L-shaped insulating film-forming film to thereby form an L-shaped insulating film on the isolation region and on a side surface of the second gate electrode-forming film; and the first fully-silicided gate electrode of the first MIS transistor and the second fully-silicided gate electrode of the second MIS transistor are electrically connected with each other.

With the method for manufacturing a semiconductor device according to one aspect of the present invention, the step of forming the first silicon film of the first gate electrode-forming film and the step of forming the second silicon film of the second gate electrode-forming film are performed separately, wherein in each of these steps, the thickness of the silicon film is set to an intended thickness, i.e., a thickness that corresponds to the thickness of the gate electrode-forming film. Therefore, it is possible to adjust the thickness of the first gate electrode-forming film and the second gate electrode-forming film to an intended thickness without adjusting the thickness of the gate electrode-forming film by means of etching as with conventional methods.

Therefore, it is possible to adjust with a high precision the thickness of both the first gate electrode-forming film and the second gate electrode-forming film, and it is possible to form with a high precision a fully-silicided gate electrode made of a metal silicide film of an intended silicide composition ratio both for the p-type MIS transistor and for the n-type MIS transistor, whereby it is possible to realize an intended threshold voltage with a high precision.

In the method for manufacturing a semiconductor device according to one aspect of the present invention, it is preferred that the step (f) includes a step (f1) of removing the second silicon film of the first gate electrode pattern to thereby expose the second insulating film of the first gate electrode pattern and removing a portion of the second gate electrode-forming film of the second gate electrode pattern that is present above the L-shaped insulating film to thereby expose the L-shaped insulating film, and a step (f2), after the step (f1), of removing the second insulating film of the first gate electrode pattern to thereby expose the first gate electrode-forming film of the first gate electrode pattern and removing a portion of the L-shaped insulating film that is present above an upper surface of the first gate electrode-forming film.

In the method for manufacturing a semiconductor device according to one aspect of the present invention, it is preferred that the step (f2) further includes a step of removing a portion of the L-shaped insulating film that is present between the first gate electrode-forming film and the second gate electrode-forming film so that an upper surface of the L-shaped insulating film is lower than that of the first gate electrode-forming film, thus forming a trench between the first gate electrode-forming film and the second gate electrode-forming film; the step (g) includes a step of filling up the trench with the metal film; and the step (h) includes a step of forming the first fully-silicided gate electrode and the second fully-silicided gate electrode so that the first fully-silicided gate electrode and the second fully-silicided gate electrode are in contact with each other above the L-shaped insulating film.

Then, as the first fully-silicided gate electrode and the second fully-silicided gate electrode are in contact with each other, it is possible to ensure the electrical connection therebetween.

In the method for manufacturing a semiconductor device according to one aspect of the present invention, it is preferred that the method further includes a step (i), after the step (h), of forming a contact plug on the first fully-silicided gate electrode and the second fully-silicided gate electrode so as to extend across the L-shaped insulating film, the contact plug electrically connecting the first fully-silicided gate electrode and the second fully-silicided gate electrode with each other.

Then, it is possible to reliably ensure the electrical connection between the first fully-silicided gate electrode and the second fully-silicided gate electrode.

In the method for manufacturing a semiconductor device according to one aspect of the present invention, it is preferred that the method further includes: a step (j), after the step (d) and before the step (e), of forming a first extension region in a portion of the first active region which is under the side of the first gate electrode pattern and forming a second extension region in a portion of the second active region which is under the side of the second gate electrode pattern; a step (k), after the step (e) and before the step (f), of forming a first source-drain region in a portion of the first active region which is under the side of the first side wall and forming a second source-drain region in a portion of the second active region which is under the side of the second side wall.

In the method for manufacturing a semiconductor device according to one aspect of the present invention, it is preferred that the method further includes a step (l), after the step (c) and before the step (d), of forming a protection film on the second silicon film; the step (d) includes a step of patterning the protection film, the second silicon film, the second insulating film, the first silicon film and the first insulating film to thereby form on the first active region the first gate electrode pattern, which includes in an upper portion thereof a first protection film made of the protection film, and patterning the protection film, the second silicon film and the second insulating film to thereby form on the second active region the second gate electrode pattern, which includes in an upper portion thereof a second protection film made of the protection film, the method further includes a step (m), after the step (k) and before the step (f), of forming a first silicide film in an upper portion of the first source-drain region and a second silicide film in an upper portion of the second source-drain region; and the step (f) further includes a step of removing the first protection film and the second protection film.

In the method for manufacturing a semiconductor device according to one aspect of the present invention, it is preferred that the step (f) includes: a step (fa) of removing the first protection film of the first gate electrode pattern to expose the second silicon film of the first gate electrode pattern and removing the second protection film of the second gate electrode pattern to expose the second gate electrode-forming film of the second gate electrode pattern; a step (fb), after the step (fa), of removing the second silicon film of the first gate electrode pattern to expose the second insulating film of the first gate electrode pattern and removing a portion of the second gate electrode-forming film of the second gate electrode pattern that is present above the L-shaped insulating film to expose the L-shaped insulating film; and a step (fc), after the step (fb), of removing the second insulating film of the first gate electrode pattern to expose the first gate electrode-forming film of the first gate electrode pattern and removing a portion of the L-shaped insulating film that is present above an upper surface of the first gate electrode-forming film.

In the method for manufacturing a semiconductor device according to one aspect of the present invention, it is preferred that the step (fc) further includes a step of removing a portion of the L-shaped insulating film that is present between the first gate electrode-forming film and the second gate electrode-forming film.

Then, it is possible to provide a trench between the first gate electrode-forming film and the second gate electrode-forming film, whereby by filling up the trench with the metal film, the first fully-silicided gate electrode and the second fully-silicided gate electrode can be made to be in contact with each other over the L-shaped insulating film through the expansion of the first fully-silicided gate electrode and the second fully-silicided gate electrode in the full silicidation step.

In the method for manufacturing a semiconductor device according to one aspect of the present invention, it is preferred that the step (fa) is a step of removing the first protection film of the first gate electrode pattern and the second protection film of the second gate electrode pattern by means of etching.

In the method for manufacturing a semiconductor device according to one aspect of the present invention, it is preferred that the step (fa) is a step of removing the first protection film of the first gate electrode pattern and the second protection film of the second gate electrode pattern by a chemical mechanical polishing method.

Then, it is possible to save an etching step.

In the method for manufacturing a semiconductor device according to one aspect of the present invention, it is preferred that the step (f) includes: a step (fa) of removing the first protection film of the first gate electrode pattern to expose the second silicon film of the first gate electrode pattern and removing a portion of the second protection film of the second gate electrode pattern that is present above the L-shaped insulating film to expose a portion of the second gate electrode-forming film of the second gate electrode pattern that is present above the L-shaped insulating film; a step (fb), after the step (fa), of removing the second silicon film of the first gate electrode pattern to expose the second insulating film of the first gate electrode pattern and removing a portion of the second gate electrode-forming film of the second gate electrode pattern that is present above the L-shaped insulating film to expose the L-shaped insulating film; and a step (fc), after the step (fb), of removing the second insulating film of the first gate electrode pattern to expose the first gate electrode-forming film of the first gate electrode pattern and removing a portion of the second protection film of the second gate electrode pattern other than the portion thereof that is present above the L-shaped insulating film to expose the second gate electrode-forming film of the second gate electrode pattern, wherein the step (fc) includes a step of removing a portion of the L-shaped insulating film that is present above an upper surface of the first gate electrode-forming film and then removing a portion of the L-shaped insulating film that is present between the first gate electrode-forming film and the second gate electrode-forming film.

Then, the remaining portion of the second protection film (more specifically, portions of the second protection film of the second gate electrode pattern other than the portion thereof that is present above the L-shaped insulating film) can be used as an etching mask to remove the second silicon film of the first gate electrode pattern and portions of the second gate electrode-forming film of the second gate electrode pattern that are exposed through the openings of the remaining second protection film.

In the method for manufacturing a semiconductor device according to one aspect of the present invention, it is preferred that the first silicon film and the second silicon film are each a polysilicon film or an amorphous silicon film.

Then, it is possible to form a first fully-silicided gate electrode made of Ni₃₁Si₁₂, Ni₃Si or Ni₂Si, for example, and to form a second fully-silicided gate electrode made of NiSi, for example.

In the method for manufacturing a semiconductor device according to one aspect of the present invention, it is preferred that the first silicon film is an SiGe film; and the second silicon film is a polysilicon film or an amorphous silicon film.

Then, it is possible to form a first fully-silicided gate electrode made of Ni₂(SiGe) or Ni₃(SiGe)₂, for example, and to form a second fully-silicided gate electrode made of NiSi, for example.

In the method for manufacturing a semiconductor device according to one aspect of the present invention, it is preferred that the metal film includes at least one metal selected from the group consisting of nickel (Ni), cobalt (Co), platinum (Pt), titanium (Ti), ruthenium (Ru), iridium (Ir) and ytterbium (Yb).

As described above, with a semiconductor device according to one aspect of the present invention and a method for manufacturing the same, the step of forming the first silicon film of the first gate electrode-forming film (the gate electrode-forming film in the P-type MIS-forming region) and the step of forming the second silicon film of the second gate electrode-forming film (the gate electrode-forming film in the N-type MIS-forming region) are performed separately, wherein in each of these steps, the thickness of the silicon film is set to an intended thickness, i.e., a thickness that corresponds to the thickness of the gate electrode-forming film. Therefore, it is possible to adjust the thickness of the first gate electrode-forming film and the second gate electrode-forming film to an intended thickness without adjusting the thickness of the gate electrode-forming film by means of etching as with conventional methods.

Therefore, it is possible to adjust with a high precision the thickness of both the first gate electrode-forming film and the second gate electrode-forming film to an intended thickness, and it is possible to form with a high precision a fully-silicided gate electrode made of a metal silicide film of an intended silicide composition ratio both for the p-type MIS transistor and for the n-type MIS transistor, whereby it is possible to realize an intended threshold voltage with a high precision.

### BRIEF DESCRIPTION OF THE DRAWINGS

FIGS. 1A to 1D are cross-sectional views taken in the gate width direction, sequentially showing important steps of a method for manufacturing a semiconductor device according to a first embodiment of the present invention.

FIGS. 2A to 2C are cross-sectional views taken in the gate width direction, sequentially showing important steps of the method for manufacturing a semiconductor device according to the first embodiment of the present invention.

FIGS. 3A to 3C are cross-sectional views taken in the gate width direction, sequentially showing important steps of the method for manufacturing a semiconductor device according to the first embodiment of the present invention.

FIGS. 4A to 4D are cross-sectional views taken in the gate length direction, sequentially showing important steps of the method for manufacturing a semiconductor device according to the first embodiment of the present invention.

FIGS. 5A to 5C are cross-sectional views taken in the gate length direction, sequentially showing important steps of the method for manufacturing a semiconductor device according to the first embodiment of the present invention.

FIG. 6 is a plan view showing a structure of a semiconductor device according to the first embodiment of the present invention.

FIG. 7 is a cross-sectional view taken in the gate length direction showing a structure of a semiconductor device according to the first embodiment of the present invention.

FIGS. 8A and 8B are cross-sectional views taken in the gate width direction, sequentially showing important steps of a method for manufacturing a semiconductor device according to a second embodiment of the present invention.

FIGS. 9A to 9C are cross-sectional views taken in the gate width direction, sequentially showing important steps of the method for manufacturing a semiconductor device according to the second embodiment of the present invention.

FIG. 10 is a plan view showing a structure of a semiconductor device according to the second embodiment of the present invention.

FIGS. 11A to 11D are cross-sectional views taken in the gate length direction, sequentially showing important steps of a method for manufacturing a semiconductor device according to a second variation of the present invention.

FIGS. 12A to 12D are cross-sectional views taken in the gate width direction, sequentially showing important steps of the method for manufacturing a semiconductor device according to the second variation of the present invention.

FIGS. 13A to 13D are cross-sectional views taken in the gate length direction, sequentially showing important steps of a conventional method for manufacturing a semiconductor device.

### DESCRIPTION OF THE PREFERRED EMBODIMENTS

Embodiments of the present invention will now be described with reference to the drawings.

### First Embodiment

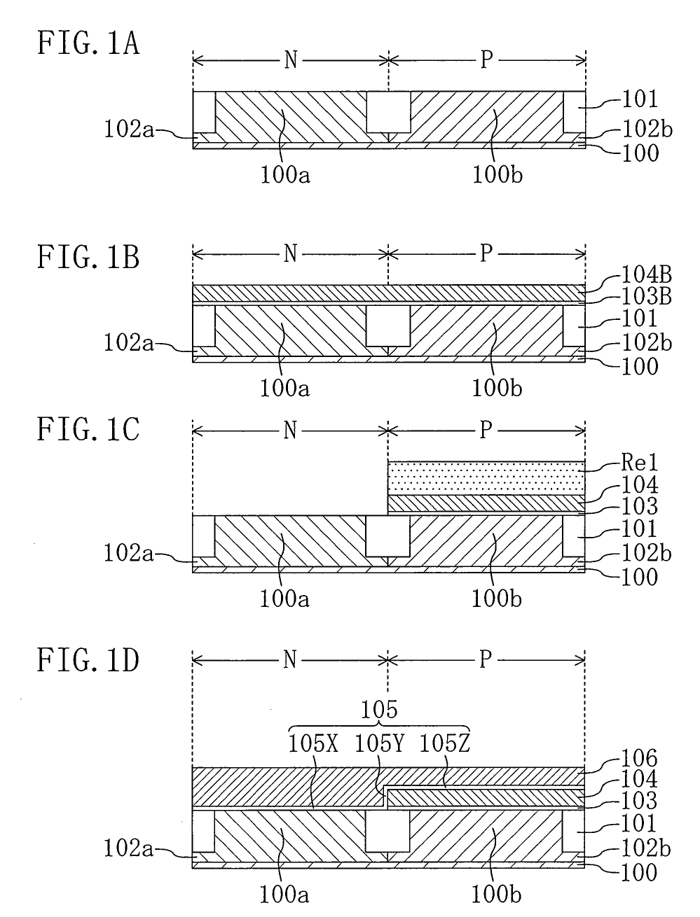

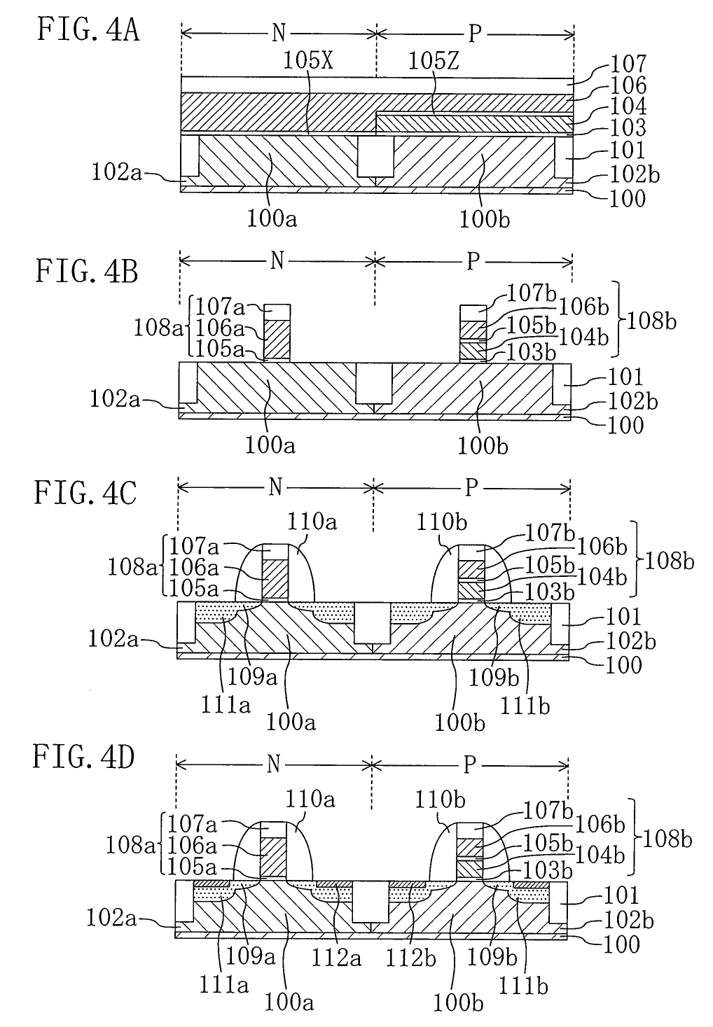

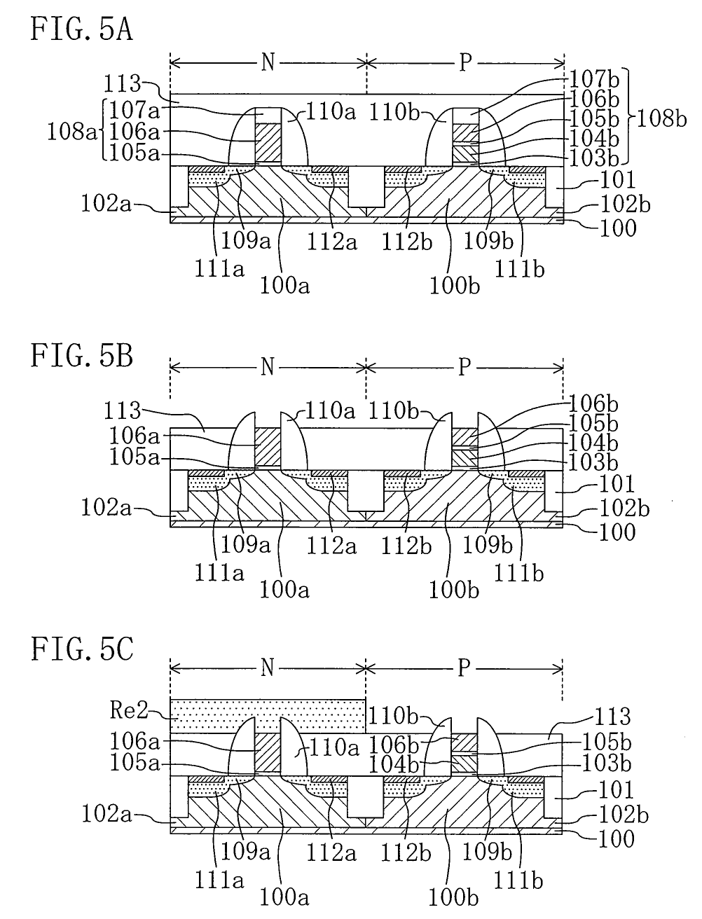

A method for manufacturing a semiconductor device according to a first embodiment of the present invention will now be described with reference to FIGS. 1A to 5C. FIGS. 1A to 3C are cross-sectional views taken in the gate width direction, sequentially showing important steps of a method for manufacturing a semiconductor device according to the first embodiment of the present invention. An N-type MIS-forming region N is shown in the left half of the figures, and a P-type MIS-forming region P is shown in the right half of the figures. FIGS. 4A to 5C are cross-sectional views taken in the gate length direction, sequentially showing important steps of the method for manufacturing a semiconductor device according to the first embodiment of the present invention. The N-type MIS-forming region and the P-type MIS-forming region are shown in these figures as being adjacent to each other for the sake of simplicity. The designation “N” in the left half of the figures denotes the N-type MIS-forming region, and the designation “P” in the right half of the figures denotes the P-type MIS-forming region.

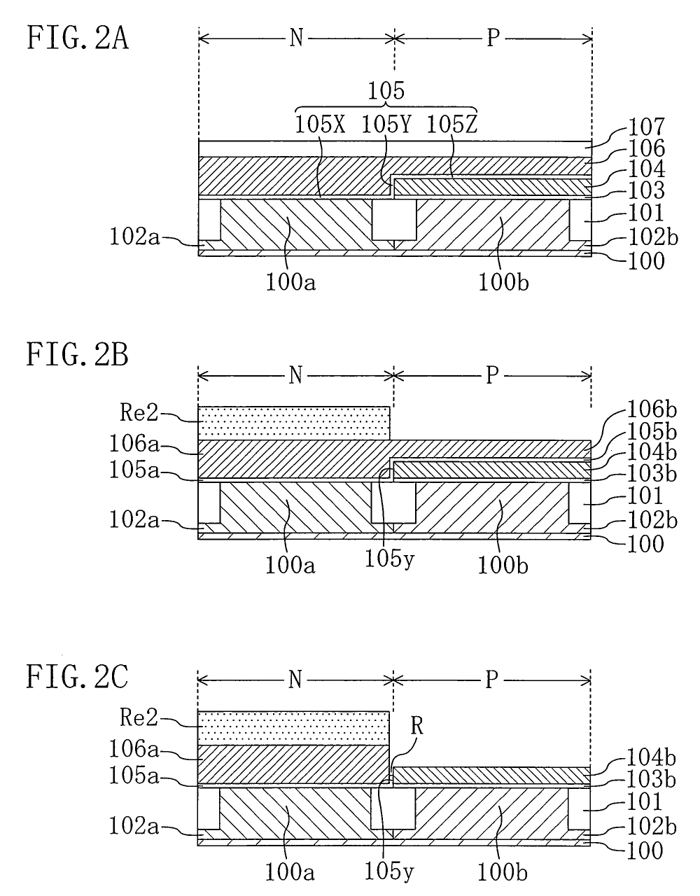

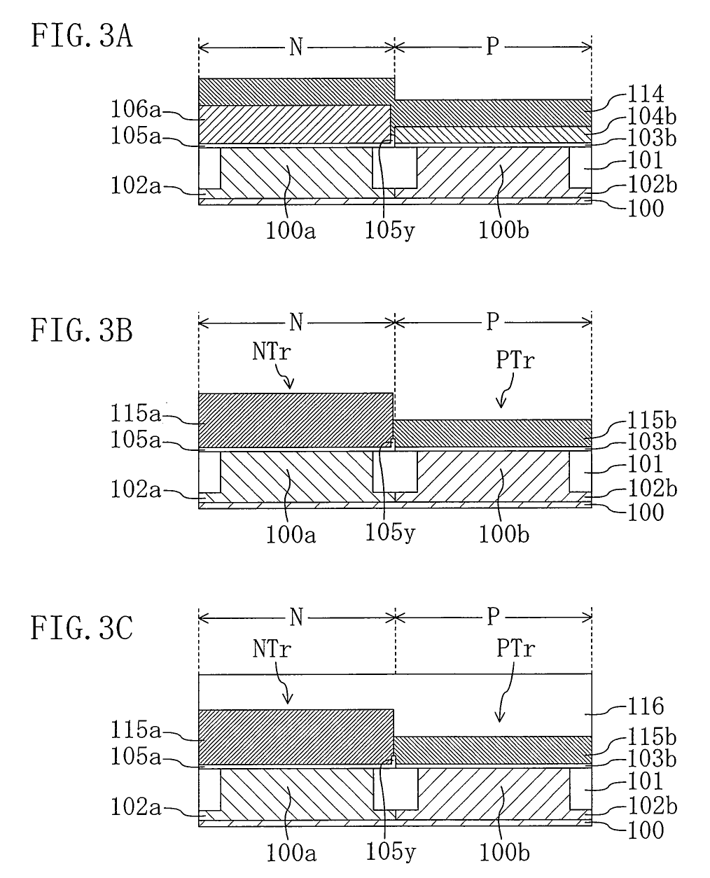

The step shown in FIG. 2A corresponds to the step shown in FIG. 4A, and the step shown in FIG. 2B corresponds to the step shown in FIG. 5C. Therefore, the description below will follow the following sequence of steps: FIGS. 1A to 1D, FIG. 2A and FIG. 4A corresponding to each other, FIGS. 4B to 4D, FIGS. 5A to 5B, FIG. 5C and FIG. 2B corresponding to each other, FIG. 2C, and FIGS. 3A to 3C.

First, as shown in FIG. 1A, an isolation region 101 being an insulating film buried in a trench is formed selectively in an upper portion of a semiconductor substrate 100 made of a p-type silicon substrate by an STI (Shallow Trench Isolation) method, for example. Thus, an active region 110a made of the semiconductor substrate 100 surrounded by the isolation region 101 is formed in the N-type MIS-forming region, and an active region 100b made of the semiconductor substrate 100 surrounded by the isolation region 101 is formed in the P-type MIS-forming region. Then, a photolithography method and an ion implantation method are used to implant the N-type MIS-forming region of the semiconductor substrate 100 with a p-type impurity such as B (boron) and the P-type MIS-forming region of the semiconductor substrate 100 with an n-type impurity such as P (phosphorus), after which the semiconductor substrate 100 is subjected to a heat treatment at 850° C. for 30 seconds, thus forming a p-type well region 102a in the N-type MIS-forming region of the semiconductor substrate 100 and an n-type well region 102b in the P-type MIS-forming region of the semiconductor substrate 100.

Then, as shown in FIG. 1B, after the surface of the semiconductor substrate 100 is washed with diluted hydrogen fluoride, a first insulating film-forming film 103B made of a silicon oxide film having a thickness of 2 nm, for example, is formed on the surface of the semiconductor substrate 100 by an ISSG (In-Situ Stream Generation) oxidation method, for example. Then, a first silicon film-forming film 104B made of a polysilicon film having a thickness of 40 nm, for example, is deposited on the first insulating film-forming film 103B by a CVD (Chemical Vapor Deposition) method, for example.

Then, as shown in FIG. 1C, the N-type MIS-forming region is opened above the semiconductor substrate 100 by a photolithography method, and a resist mask pattern Re1 is formed so as to cover the P-type MIS-forming region, after which a portion of the first silicon film-forming film 104B and a portion of the first insulating film-forming film 103B that are present in the N-type MIS-forming region are successively removed by dry etching while using the resist mask pattern Re1 as a mask.

Thus, a first silicon film 104 made of a polysilicon film having a thickness of 40 nm is formed on the active region 100b in the P-type MIS-forming region, with a first insulating film (herein the first insulating film includes a first gate insulating film-forming film formed on the active region 100b in the P-type MIS-forming region) 103 made of a silicon oxide film having a thickness of 2 nm being interposed therebetween, as shown in FIG. 1C. The thickness of the first silicon film 104 is adjusted by using a CVD method.

Then, as shown in FIG. 1D, the resist mask pattern Re1 is removed, and the surface of the semiconductor substrate 100 is washed with diluted hydrogen fluoride. Then, a second insulating film 105 made of a silicon oxide film having a thickness of 2 nm, for example, is formed across the entire surface of the semiconductor substrate 100.

As shown in FIG. 1D, the second insulating film 105, which is formed across the entire surface of the semiconductor substrate 100, includes a second gate insulating film-forming film 105x formed on the active region 100a in the N-type MIS-forming region, an L-shaped insulating film-forming film 105Y extending from the top of the isolation region 101 along a side surface of the first silicon film 104 in the gate width direction, and an etching stopper film-forming film 105Z formed on the first silicon film 104.

Then, after a polysilicon film having a thickness of 120 nm, for example, is deposited on the second insulating film 105 by a CVD method, for example, the surface of the polysilicon film is flattened by a chemical mechanical polishing (CMP) method. Thus, a second silicon film 106 is formed across the entire surface of the semiconductor substrate 100, wherein the second silicon film 106 is a polysilicon film having a thickness of 100 nm in the N-type MIS-forming region and a thickness of 60 nm in the P-type MIS-forming region.

Thus, as shown in FIG. 1D, the second silicon film 106 made of a polysilicon film having a thickness of 100 nm is formed on the active region 100a in the N-type MIS-forming region, with the second gate insulating film-forming film 105X made of a silicon oxide film having a thickness of 2 nm being interposed therebetween. The thickness of the second silicon film 106 is adjusted by using a CVD method and a CMP method.

Then, as shown in FIGS. 2A and 4A, a protection film 107 made of a silicon oxide film is formed on the second silicon film 106 by a CVD method, for example. The step shown in FIG. 2A corresponds to the step shown in FIG. 4A, wherein FIG. 2A shows a cross-sectional view taken in the gate width direction while FIG. 4A shows a cross-sectional view taken in the gate length direction.

Then, as shown in FIG. 4B, a resist mask pattern (not shown) having a gate pattern shape is formed on the protection film 107 by a photolithography method. Then, using the resist mask pattern as a mask, portions of the protection film 107, the second silicon film 106, the second gate insulating film-forming film 105X and the L-shaped insulating film-forming film 105Y that are exposed through the openings of the resist mask pattern are successively removed by dry etching in the N-type MIS-forming region. Then, portions of the protection film 107, the second silicon film 106, the etching stopper film-forming film 105Z, the first silicon film 104 and the first insulating film 103 including the first gate insulating film-forming film that are exposed through the openings of the resist mask pattern are successively removed in the P-type MIS-forming region.

Thus, a second gate insulating film 105a, a second gate electrode-forming film 106a and a second protection film 107a having the gate pattern shape are successively formed on the active region 100a in the N-type MIS-forming region. Thus, as shown in FIG. 4B, a second gate electrode pattern 108a is produced, including the second gate insulating film 105a and the second gate electrode-forming film 106a, with the second protection film 107a formed in an upper portion thereof. The thickness of the second gate electrode-forming film 106a is adjusted by using a CVD method and a CMP method.

A first gate insulating film 103b, a first gate electrode-forming film 104b, an etching stopper film 105b, a silicon film 106b and a first protection film 107b having the gate pattern shape are successively formed on the active region 100b in the P-type MIS-forming region. Thus, as shown in FIG. 4B, a first gate electrode pattern 108b is produced, including the first gate insulating film 103b and the first gate electrode-forming film 104b, with the first protection film 107b formed in an upper portion thereof. The thickness of the first gate electrode-forming film 104b is adjusted by using a CVD method.

Although not shown in FIG. 4B, being a cross-sectional view taken in the gate length direction, an L-shaped insulating film (see 105y shown in FIG. 2B to be discussed later) having an L-shaped cross section is formed so as to extend from the top of the isolation region 101 along a side surface of the second gate electrode-forming film 106a in the gate width direction.

Then, as shown in FIG. 4C, the active region 100a in the N-type MIS-forming region is implanted with an n-type impurity using the second gate electrode pattern 108a as a mask, thereby forming, in a self-aligned manner, an n-type extension region 109a under the side of the second gate electrode pattern 108a in the active region 100a. The active region 100b in the P-type MIS-forming region is implanted with a p-type impurity using the first gate electrode pattern 108b as a mask, thereby forming, in a self-aligned manner, a p-type extension region 109b in a portion of the active region 100b which is under the side of the first gate electrode pattern 108b.

Then, after a silicon nitride film having a thickness of 50 nm, for example, is deposited across the entire surface of the semiconductor substrate 100 by a CVD method, for example, so as to cover the gate electrode patterns 108a and 108b, the silicon nitride film is subjected to an anisotropic etching process to thereby form side walls 110a and 110b, each made of a silicon nitride film, on the side surfaces of the gate electrode patterns 108a and 108b, respectively.

Then, the active region 100a in the N-type MIS-forming region is implanted with an n-type impurity using the second gate electrode pattern 108a and the side wall 110a as a mask, and the active region 100b in the P-type MIS-forming region is implanted with a p-type impurity using the first gate electrode pattern 108b and the side wall 110b as a mask. Then, a heat treatment is performed, whereby an n-type source-drain region 111a having a junction deeper than that of the n-type extension region 109a is formed in a self-aligned manner in a portion of the active region 100a in the N-type MIS-forming region which is under the side of the side wall 110a, and a p-type source-drain region 111b having a junction deeper than that of the p-type extension region 109b is formed in a self-aligned manner in a portion of the active region 100b in the P-type MIS-forming region which is under the side of the side wall 110b.

Then, as shown in FIG. 4D, a natural oxide film (not shown) formed on the surface of the n-type source-drain region 111a and the p-type source-drain region 111b is removed, and a metal film (not shown) of nickel having a thickness of 10 nm, for example, is deposited across the entire surface of the semiconductor substrate 100 by a sputtering method. Then, the semiconductor substrate 100 is subjected to a first RTA (Rapid Thermal Annealing) process in a nitrogen atmosphere at 320° C. so that silicon in the source-drain regions 111a and 111b is allowed to react with nickel in the metal film, thereby making these portions into metal silicide portions. Then, the semiconductor substrate 100 is immersed in an etchant made of a mixture of sulfuric acid and a hydrogen peroxide solution to thereby remove unreacted portions of the metal film remaining on the isolation region 101, the protection films 107a and 107b, the side walls 110a and 110b, etc., after which the semiconductor substrate 100 is subjected to a second RTA process at a temperature (e.g., 550° C.) higher than that of the first RTA process.

Thus, a silicide film 112a is formed in the N-type MIS-forming region by allowing an upper portion of the n-type source-drain region 111a to react with a metal film. In the P-type MIS-forming region, a silicide film 112b is formed by allowing an upper portion of the p-type source-drain region 111b to react with a metal film.

Then, as shown in FIG. 5A, a first interlayer insulating film 113 made of a silicon oxide film, for example, is formed across the entire surface of the semiconductor substrate 100 so as to cover the gate electrode patterns 108a and 108b, and then the surface of the first interlayer insulating film 113 is flattened by a CMP method.

Then, as shown in FIG. 5B, a dry or wet etching process having a high etching selectivity to the polysilicon film (the second gate electrode-forming film 106a and the silicon film 106b) and the silicon nitride film (the side walls 110a and 110b) is performed so as to remove portions of the first interlayer insulating film 113 (a silicon oxide film) that are present above the upper surface of the second gate electrode-forming film 106a and the silicon film 106b, the second protection film 107a (a silicon oxide film) in the N-type MIS-forming region, and the first protection film 107b (a silicon oxide film) in the P-type MIS-forming region.

Thus, as shown in FIG. 5B, in the N-type MIS-forming region, the upper surface of the second gate electrode-forming film 106a of the second gate electrode pattern 108a is exposed. In the P-type MIS-forming region, the upper surface of the silicon film 106b of the first gate electrode pattern 108b is exposed.

Then, as shown in FIGS. 5C and 2B, a resist mask pattern Re2 is formed on the semiconductor substrate 100 by a photolithography method. The step shown in FIG. 2B corresponds to the step shown in FIG. 5C, wherein FIG. 2B shows a cross-sectional view taken in the gate width direction while FIG. 5C shows a cross-sectional view taken in the gate length direction.

Then, as shown in FIG. 2C, a dry etching process is performed using the resist mask pattern Re2 as a mask so that a portion of the second gate electrode-forming film 106a of the second gate electrode pattern 108a that is present above an L-shaped insulating film 105y is removed in the N-type MIS-forming region to thereby expose the upper surface of the L-shaped insulating film 105y. In the P-type MIS-forming region, the silicon film 106b of the first gate electrode pattern 108b is removed to thereby expose the upper surface of the etching stopper film 105b of the first gate electrode pattern 108b.

Then, a dry or wet etching process is performed using the resist mask pattern Re2 as a mask so that a portion of the L-shaped insulating film 105y that is present above the upper surface of the first gate electrode-forming film 104b is removed in the N-type MIS-forming region to thereby expose a portion of the L-shaped insulating film 105y that is present between the second gate electrode-forming film 106a and the first gate electrode-forming film 104b. In the P-type MIS-forming region, the etching stopper film 105b of the first gate electrode pattern 108b is removed to thereby expose the upper surface of the first gate electrode-forming film 104b of the first gate electrode pattern 108b. Since the etching characteristics of the etching stopper film (a silicon oxide film) 105b are different from those of the first gate electrode-forming film (a polysilicon film) 104b, it is possible to selectively remove only the etching stopper film 105b. At this point, the upper surface of the L-shaped insulating film 105y is continuous with the upper surface of the first gate electrode-forming film 104b.

Then, a further dry or wet etching process is performed using the resist mask pattern Re2 as a mask so that a portion of the L-shaped insulating film 105y that is present between the second gate electrode-forming film 106a and the first gate electrode-forming film 104b is removed to make the upper surface of the L-shaped insulating film 105y lower than that of the first gate electrode-forming film 104b, thus forming a trench R between the second gate electrode-forming film 106a and the first gate electrode-forming film 104b. Since the etching characteristics of the L-shaped insulating film (a silicon oxide film) 105y are different from those of the first gate electrode-forming film (a polysilicon film) 104b, it is possible to selectively remove only the L-shaped insulating film 105y.

Thus, as shown in FIG. 2C, the second gate electrode-forming film 106a made of a polysilicon film having a thickness of 100 nm is formed on the active region 100a in the N-type MIS-forming region, with the second gate insulating film 105a made of a silicon oxide film having a thickness of 2 nm being interposed therebetween, and the first gate electrode-forming film 104b made of a polysilicon film having a thickness of 40 nm is formed on the active region 100b in the P-type MIS-forming region, with the first gate insulating film 103b made of a silicon oxide film having a thickness of 2 nm being interposed therebetween.

As shown in FIG. 2C, the L-shaped insulating film 105y is integral with the second gate insulating film 105a, extends from the top of the isolation region 101 along a side surface of the second gate electrode-forming film 106a in the gate width direction, and has an L-shaped cross section. The upper surface of the L-shaped insulating film 105y is lower than that of the first gate electrode-forming film 104b in the P-type MIS-forming region.

Then, as shown in FIG. 3A, after the resist mask pattern Re2 is removed, a metal film 114 of nickel having a thickness of 70 nm, for example, is deposited by a sputtering method, for example, across the entire surface of the semiconductor substrate 100 so as to cover the second gate electrode-forming film 106a in the N-type MIS-forming region and the first gate electrode-forming film 104b in the P-type MIS-forming region.

Then, as shown in FIG. 3B, the semiconductor substrate 100 is subjected to an RTA process in a nitrogen atmosphere at 380° C. so that silicon of the second gate electrode-forming film 106a in the N-type MIS-forming region and the first gate electrode-forming film 104b in the P-type MIS-forming region is allowed to react with nickel of the metal film 114, thereby making these portions into metal silicide portions. Then, unreacted portions of the metal film 114 remaining on the semiconductor substrate 100 are removed.

Thus, in the N-type MIS-forming region, the entirety of the second gate electrode-forming film 106a is allowed to react with the metal film 114 to thereby form a FUSI gate electrode 115a made of NiSi, for example. In the P-type MIS-forming region, the entirety of the first gate electrode-forming film 104b is allowed to react with the metal film 114 to thereby form a FUSI gate electrode 115b made of Ni₃Si, for example. In the P-type MIS-forming region, since the thickness of the metal film 114 (70 nm) is larger than that of the first gate electrode-forming film 104b (40 nm), a more metal-rich silicide film is formed as the duration of the RTA process in the full silicidation step is increased. Thus, it is possible to selectively form, as the FUSI gate electrode 115b, Ni₃₁Si₁₂ or Ni₂Si as well as Ni₃Si by controlling the duration of the RTA process. In the N-type MIS-forming region, since the thickness of the metal film 114 (70 nm) is smaller than that of the second gate electrode-forming film 106a (100 nm), the silicide composition ratio is not changed substantially by increasing the duration of the RTA process.

In this process, the FUSI gate electrodes 115a and 115b expand as a whole. Therefore, as shown in FIG. 3B, the FUSI gate electrode 115a in the N-type MIS-forming region and the FUSI gate electrode 115b in the P-type MIS-forming region contact each other over the L-shaped insulating film 105y, whereby it is possible to ensure the electrical connection between the FUSI gate electrode 115a and the FUSI gate electrode 115b.

Then, as shown in FIG. 3C, a second interlayer insulating film 116 is formed across the entire surface of the semiconductor substrate 100 by a CVD method, for example, so as to cover the FUSI gate electrodes 115a and 115b, after which the surface of the second interlayer insulating film 116 is flattened by a CMP method.

Then, as with a method for manufacturing a semiconductor device having normal MIS transistors, a resist mask pattern (not shown) is formed on the second interlayer insulating film 116, and then a dry etching process is performed using the resist mask pattern as a mask to thereby form contact holes that are running through the first interlayer insulating film 113 and the second interlayer insulating film 116 to reach the upper surface of the silicide films 112a and 112b formed in an upper portion of the source-drain regions 111a and 111b, respectively.

Then, a barrier metal film, which is obtained by successively depositing titanium and titanium nitride, is formed on the bottom portion and the side wall portion of each contact hole by a sputtering method or a CVD method. Then, a tungsten film is deposited on the second interlayer insulating film 116 by a CVD method so as to fill up the contact holes, and then portions of the tungsten film that are present outside the contact holes are removed by a CMP method. This produces contact plugs (see 117a and 117b shown in FIG. 7 to be discussed later) obtained by filling up the contact holes with a tungsten film, with the barrier metal film being interposed therebetween. Then, metal wiring (not shown) is formed on the second interlayer insulating film 116 so as to be electrically connected to the contact plugs.

A semiconductor device of the present embodiment can be produced as described above.

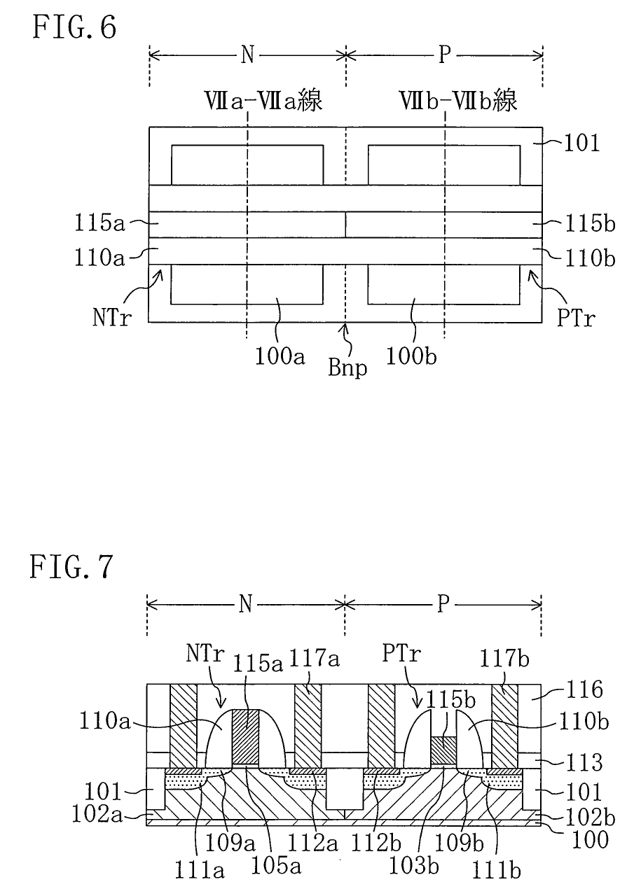

The structure of the semiconductor device according to the first embodiment of the present invention will now be described with reference to FIGS. 6 and 7. FIG. 6 is a plan view showing the structure of the semiconductor device according to the first embodiment of the present invention. The N-type MIS-forming region N is shown in the left half of the figure, and the P-type MIS-forming region P is shown in the right half of the figure. Moreover, the designation “Bnp” appearing in the figure at the boundary between the N-type MIS-forming region N and the P-type MIS-forming region P represents the well boundary. FIG. 7 is a cross-sectional view taken in the gate length direction showing the structure of the semiconductor device according to the first embodiment of the present invention. Specifically, the cross-sectional view shown in the left half of the figure is taken along line VIIa-VIIa in FIG. 6 and that in the right half is taken along line VIIb-VIIb in FIG. 6. The N-type MIS-forming region and the P-type MIS-forming region are shown in the figure as being adjacent to each other for the sake of simplicity. The designation “N” in the left half of the figure denotes the N-type MIS-forming region, and the designation “P” in the right half of the figure denotes the P-type MIS-forming region.

As shown in FIG. 6, the active region 100a surrounded by the isolation region 101 is formed in the N-type MIS-forming region, and the active region 100b surrounded by the isolation region 101 is formed in the P-type MIS-forming region. The FUSI gate electrode 115a is formed on the active region 100a in the N-type MIS-forming region, and the FUSI gate electrode 115b is formed on the active region 100b in the P-type MIS-forming region. The side walls 110a and 110b are formed on the side surfaces of the FUSI gate electrodes 115a and 115b, respectively.

Thus, in the present embodiment, as shown in FIG. 6, the FUSI gate electrode 115a in the N-type MIS-forming region and the FUSI gate electrode 115b in the P-type MIS-forming region are in contact with each other along the side surfaces thereof in the gate width direction.

As shown in FIG. 7, the isolation region 101 obtained by filling a trench with an insulating film is formed in an upper portion of the semiconductor substrate 100 so as to partition the N-type MIS-forming region and the P-type MIS-forming region from each other. An n-type MIS transistor NTr is provided in the N-type MIS-forming region, whereas a p-type MIS transistor PTr is provided in the P-type MIS-forming region.

As shown in FIG. 7, the n-type MIS transistor NTr includes the p-type well region 102a formed in the N-type MIS-forming region of the semiconductor substrate 100, an active region surrounded by the isolation region 101 in the p-type well region 102a, the second gate insulating film 105a formed on the active region, the FUSI gate electrode 115a formed on the second gate insulating film 105a, the side wall 110a formed on the side surface of the FUSI gate electrode 115a, the n-type extension region 109a formed in a portion of the active region which is under the side of the FUSI gate electrode 115a, the n-type source-drain region 111a formed in a portion of the active region which is under the side of the side wall 110a, and the silicide film 112a formed in an upper portion of the n-type source-drain region 111a.

Similarly, as shown in FIG. 7, the p-type MIS transistor PTr includes the n-type well region 102b formed in the P-type MIS-forming region of the semiconductor substrate 100, an active region surrounded by the isolation region 101 in the n-type well region 102b, the first gate insulating film 103b formed on the active region, the FUSI gate electrode 115b formed on the first gate insulating film 103b, the side wall 110b formed on the side surface of the FUSI gate electrode 115b, the p-type extension region 109b formed in a portion of the active region which is under the side of the FUSI gate electrode 115b, the p-type source-drain region 111b formed in a portion of the active region which is under the side of the side wall 110b, and the silicide film 112b formed in an upper portion of the p-type source-drain region 111b.

The first interlayer insulating film 113 is formed on the semiconductor substrate 100, and the second interlayer insulating film 116 is formed on the first interlayer insulating film 113 so as to cover the FUSI gate electrodes 115a and 115b. Contact plugs 117a and 117b are formed, which are running through the first interlayer insulating film 113 and the second interlayer insulating film 116 and are electrically connected to the silicide films 112a and 112b, respectively.

According to the present embodiment, the step of forming the first silicon film 104 of the first gate electrode-forming film 104b (see the step shown in FIGS. 1B and 1C) and the step of forming the second silicon film 106 of the second gate electrode-forming film 106a (see the step shown in FIG. 1D) are performed separately, wherein in each of these steps, the thickness of the silicon film 104 (or 106) is set to an intended thickness, i.e., a thickness that corresponds to the thickness of the gate electrode-forming film 104b (or 106a). Specifically, the thickness adjustment for the first silicon film 104 is performed by a CVD method, and that for the second silicon film 106 is performed by a CVD method and a CMP method.

Therefore, in the present embodiment, the second gate electrode-forming film 106a whose thickness is adjusted is formed on the active region 100a in the N-type MIS-forming region by using a CVD method and a CMP method, and the first gate electrode-forming film 104b whose thickness is adjusted is formed on the active region 100b in the P-type MIS-forming region by using a CVD method.

Thus, in the present embodiment, the thicknesses of the second gate electrode-forming film 106a in the N-type MIS-forming region and the first gate electrode-forming film 104b in the P-type MIS-forming region can be adjusted to intended thicknesses by means of deposition (and polishing), instead of etching as with conventional methods.

Note that thickness adjustment means based on deposition (and polishing) offers better controllability than that based on etching.

Therefore, in the present embodiment, the thickness of the gate electrode-forming film 104b in the P-type MIS-forming region can be adjusted with a higher precision, as compared with a gate electrode-forming film in the P-type MIS-forming region whose thickness is adjusted by means of etching as with conventional methods.

Thus, in the present embodiment, it is possible to suppress variations in the polysilicon film thickness between different gate electrode-forming films 104b, whereby it is possible to suppress variations in the ratio between the polysilicon film thickness and the metal film thickness. Therefore, it is possible to suppress variations in the silicide composition ratio in the metal silicide film between different FUSI gate electrodes 115b.

In addition, it is possible in the present embodiment to suppress the roughness of the polysilicon film surface within the same gate electrode-forming film 104b, whereby it is possible to suppress variations in the ratio between the polysilicon film thickness and the metal film thickness. Thus, it is possible to suppress variations in the silicide composition ratio in the metal silicide film within the same FUSI gate electrode 115b, i.e., to improve the uniformity of the silicide composition ratio in the metal silicide film.

Therefore, in the present embodiment, the thickness of the second gate electrode-forming film 106a and that of the first gate electrode-forming film 104b can both be adjusted with a high precision to their intended thicknesses, respectively. As a result, it is possible to realize with a high precision the FUSI gate electrodes 115a and 115b each being made of a metal silicide film of an intended silicide composition ratio both for the n-type MIS transistor and for the p-type MIS transistor, whereby it is possible to realize with a high precision an intended threshold voltage for each of the MIS transistors.

### Second Embodiment

Differences between a second embodiment of the present invention and the first embodiment above will now be described below.

In the first embodiment, in order to ensure the electrical connection between the FUSI gate electrode 115a in the N-type MIS-forming region and the FUSI gate electrode 115b in the P-type MIS-forming region, a portion of the L-shaped insulating film 105y that is present between the second gate electrode-forming film 106a and the first gate electrode-forming film 104b is removed so as to make the upper surface of the L-shaped insulating film 105y lower than that of the first gate electrode-forming film 104b, thus forming the trench R between the second gate electrode-forming film 106a and the first gate electrode-forming film 104b, as shown in FIG. 2C. Then, through the expansion of the FUSI gate electrode 115a and the FUSI gate electrode 115b in the full silicidation step, the FUSI gate electrode 115a and the FUSI gate electrode 115b are made to be in contact with each other over the L-shaped insulating film 105y.

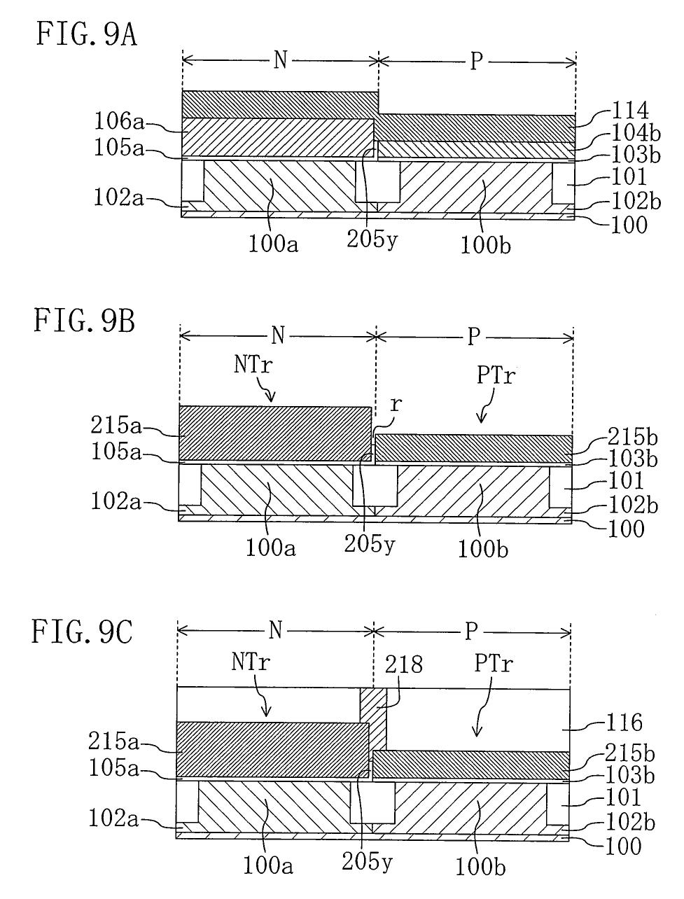

In contrast, in the second embodiment, in order to ensure the electrical connection between a FUSI gate electrode 215a in the N-type MIS-forming region and a FUSI gate electrode 215b in the P-type MIS-forming region, a contact plug 218 for electrically connecting the FUSI gate electrode 215a and the FUSI gate electrode 215b with each other is formed on the FUSI gate electrode 215a and the FUSI gate electrode 215b, extending across an L-shaped insulating film 205y, as shown in FIG. 9C to be discussed later, after the full silicidation step.

Thus, as compared with the first embodiment, the present embodiment can more reliably ensure the electrical connection between the FUSI gate electrode in the N-type MIS-forming region and the FUSI gate electrode in the P-type MIS-forming region.

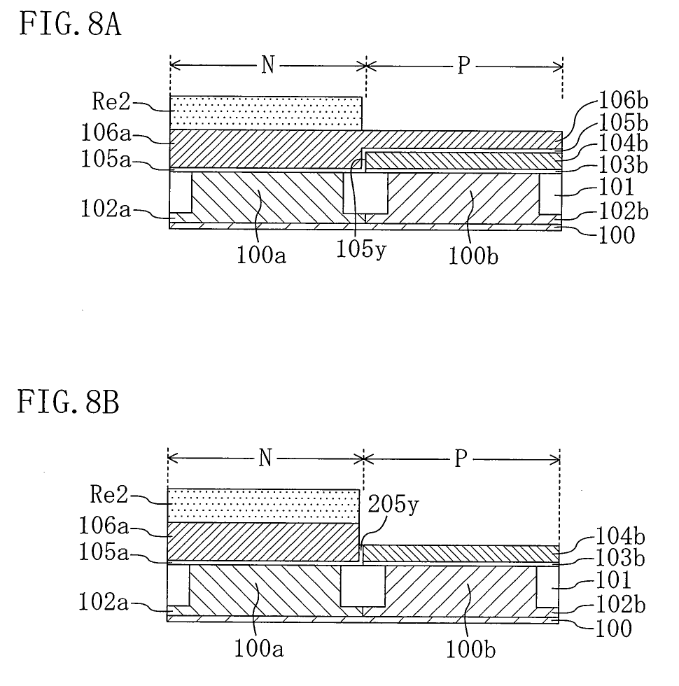

A method for manufacturing a semiconductor device according to the second embodiment of the present invention will now be described with reference to FIGS. 8A to 9C. FIGS. 8A to 9C are cross-sectional views taken in the gate width direction, sequentially showing important steps of the method for manufacturing a semiconductor device according to the second embodiment of the present invention. The N-type MIS-forming region N is shown in the left half of the figures, and the P-type MIS-forming region P is shown in the right half of the figures. In FIGS. 8A to 9C, like elements to those of the semiconductor device of the first embodiment above are denoted by like reference numerals. In the following description of the second embodiment, what has already been described in the first embodiment will not be described redundantly.

First, steps shown in FIGS. 1A to 1D, FIGS. 2A and 4A, FIGS. 4B to 4D and FIGS. 5A to 5B are performed successively.

Then, as shown in FIG. 8A, the resist mask pattern Re2 is formed on the semiconductor substrate 100 by a photolithography method (corresponding to the step shown in FIGS. 2B and 5C).

Then, as shown in FIG. 8B, a dry etching process is performed using the resist mask pattern Re2 as a mask so that a portion of the second gate electrode-forming film 106a of the second gate electrode pattern 108a that is present above the L-shaped insulating film 205y is removed in the N-type MIS-forming region to thereby expose the upper surface of the L-shaped insulating film 205y. In the P-type MIS-forming region, the silicon film 106b of the first gate electrode pattern 108b is removed to thereby expose the upper surface of the etching stopper film 105b of the first gate electrode pattern 108b.

Then, a dry or wet etching process is performed using the resist mask pattern Re2 as a mask so that a portion of the L-shaped insulating film 205y that is present above the upper surface of the first gate electrode-forming film 104b is removed in the N-type MIS-forming region to thereby expose a portion of the L-shaped insulating film 205y that is present between the second gate electrode-forming film 106a and the first gate electrode-forming film 104b. In the P-type MIS-forming region, the etching stopper film 105b of the first gate electrode pattern 108b is removed to thereby expose the upper surface of the first gate electrode-forming film 104b of the first gate electrode pattern 108b. Since the etching characteristics of the etching stopper film (a silicon oxide film) 105b are different from those of the first gate electrode-forming film (a polysilicon film) 104b, it is possible to selectively remove only the etching stopper film 105b.

Thus, as shown in FIG. 8B, the second gate electrode-forming film 106a made of a polysilicon film having a thickness of 100 nm is formed on the active region 100a in the N-type MIS-forming region, with the second gate insulating film 105a made of a silicon oxide film having a thickness of 2 nm being interposed therebetween, and the first gate electrode-forming film 104b made of a polysilicon film having a thickness of 40 nm is formed on the active region 100b in the P-type MIS-forming region, with the first gate insulating film 103b made of a silicon oxide film having a thickness of 2 nm being interposed therebetween.

As shown in FIG. 8B, the L-shaped insulating film 205y is integral with the second gate insulating film 105a, extends from the top of the isolation region 101 along a side surface of the second gate electrode-forming film 106a in the gate width direction, and has an L-shaped cross section. The upper surface of the L-shaped insulating film 205y is continuous with the upper surface of the first gate electrode-forming film 104b.

Then, as shown in FIG. 9A, after the resist mask pattern Re2 is removed, a metal film 114 of nickel having a thickness of 70 nm, for example, is deposited by a sputtering method, for example, across the entire surface of the semiconductor substrate 100 so as to cover the second gate electrode-forming film 106a in the N-type MIS-forming region and the first gate electrode-forming film 104b in the P-type MIS-forming region.

Then, as shown in FIG. 9B, the semiconductor substrate 100 is subjected to an RTA process in a nitrogen atmosphere at 380° C. so that silicon of the second gate electrode-forming film 106a in the N-type MIS-forming region and the first gate electrode-forming film 104b in the P-type MIS-forming region is allowed to react with nickel of the metal film 114, thereby making these portions into metal silicide portions. Then, unreacted portions of the metal film 114 remaining on the semiconductor substrate 100 are removed.

Thus, in the N-type MIS-forming region, the entirety of the second gate electrode-forming film 106a is allowed to react with the metal film 114 to thereby form the FUSI gate electrode 215a made of NiSi, for example. In the P-type MIS-forming region, the entirety of the first gate electrode-forming film 104b is allowed to react with the metal film 114 to thereby form the FUSI gate electrode 215b made of Ni₃Si, for example. It is possible to selectively form, as the FUSI gate electrode 215b, Ni₃₁Si₁₂ or Ni₂Si as well as Ni₃Si by controlling the duration of the RTA process in the full silicidation step.

In this process, the FUSI gate electrode 215a and 215b expand as a whole. However, as shown in FIG. 9B, a trench r may be formed between the FUSI gate electrode 215a and the FUSI gate electrode 215b, whereby the FUSI gate electrode 215a and the FUSI gate electrode 215b may not be in contact with each other over the L-shaped insulating film 205y.

Then, as shown in FIG. 9C, the second interlayer insulating film 116 is formed across the entire surface of the semiconductor substrate 100 by a CVD method, for example, so as to cover the FUSI gate electrodes 215a and 215b, after which the surface of the second interlayer insulating film 116 is flattened by a CMP method.

Then, a resist mask pattern (not shown) is formed on the second interlayer insulating film 116, and then a dry etching process is performed using the resist mask pattern as a mask to thereby form contact holes that are running through the first interlayer insulating film 113 and the second interlayer insulating film 116 to expose the upper surface of the L-shaped insulating film 205y and the upper surfaces of the FUSI gate electrode 215a and 215b, and contact holes that are running through the first interlayer insulating film 113 and the second interlayer insulating film 116 to expose the upper surface of the silicide layers 112a and 112b formed in an upper portion of the source-drain regions 111a and 111b (see FIG. 7).

Then, a barrier metal film, which is obtained by successively depositing titanium and titanium nitride, is formed on the bottom portion and the side wall portion of each contact hole by a sputtering method or a CVD method. Then, a tungsten film is deposited on the second interlayer insulating film 116 by a CVD method so as to fill up the contact holes, and then portions of the tungsten film that are present outside the contact holes are removed by a CMP method. This produces contact plugs (see 218 shown in FIGS. 9C and 117a and 117b shown in FIG. 7 discussed above) obtained by filling up the contact holes with a tungsten film, with the barrier metal film being interposed therebetween. Then, metal wiring (not shown) is formed on the second interlayer insulating film 116 so as to be electrically connected to the contact plugs.

A semiconductor device of the present embodiment can be produced as described above.

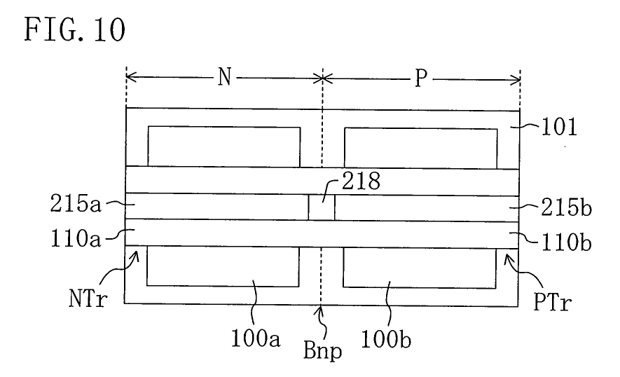

The structure of the semiconductor device according to the second embodiment of the present invention will now be described with reference to FIG. 10. FIG. 10 is a plan view showing the structure of the semiconductor device according to the second embodiment of the present invention. The N-type MIS-forming region N is shown in the left half of the figure, and the P-type MIS-forming region P is shown in the right half of the figure. Moreover, the designation “Bnp” appearing in the figure at the boundary between the N-type MIS-forming region N and the P-type MIS-forming region P represents the well boundary.

As shown in FIG. 10, the active region 100a surrounded by the isolation region 101 is formed in the N-type MIS-forming region, and the active region 100b surrounded by the isolation region 101 is formed in the P-type MIS-forming region. The FUSI gate electrode 215a is formed on the active region 100a in the N-type MIS-forming region, and the FUSI gate electrode 215b is formed on the active region 100b in the P-type MIS-forming region. The side walls 110a and 110b are formed on the side surfaces of the FUSI gate electrodes 215a and 215b, respectively.

Thus, in the present embodiment, as shown in FIG. 10, the FUSI gate electrode 215a in the N-type MIS-forming region and the FUSI gate electrode 215b in the P-type MIS-forming region are in contact with each other via the contact plug 218, which is formed on the FUSI gate electrode 215a and 215b to extend across the L-shaped insulating film.

According to the present embodiment, even if the trench r is formed between the FUSI gate electrode 215a in the N-type MIS-forming region and the FUSI gate electrode 215b in the P-type MIS-forming region in the full silicidation step so that the FUSI gate electrodes are not in contact with each other along side surfaces thereof in the gate width direction, i.e., even if the FUSI gate electrodes do not come into contact with each other through the expansion thereof in the full silicidation step, it is possible to reliably ensure the electrical connection between the FUSI gate electrode 215a and the FUSI gate electrode 215b by the presence of the contact plug 218, which is formed on the FUSI gate electrode 215a and the FUSI gate electrode 215b to extend across the L-shaped insulating film 205y.

As shown in FIG. 9C, the formation of the contact plug 218 can be done in the same step as the step of forming contact plugs (see 117a and 117b shown in FIG. 7 discussed above) reaching the upper surfaces of the silicide films 112a and 112b, and will not increase the number of steps.

In the second embodiment, the contact plug 218 reaching the upper surface of the L-shaped insulating film 205y as shown in FIG. 9C is used as a contact plug that electrically connects the FUSI gate electrode 215a and the FUSI gate electrode 215b with each other. However, the present invention is not limited to this.

For example, the contact plug may be a contact plug that runs through a portion of the L-shaped insulating film 205y present between the FUSI gate electrode 215a and the FUSI gate electrode 215b to reach the upper surface of the isolation region 101.

### First Variation

A method for manufacturing a semiconductor device according to a first variation of the present invention will now be described. The following description will focus on differences between this variation and the first embodiment described above.

In the first embodiment, as shown in FIG. 3A, the full silicidation step is performed in a state where the metal film 114 of nickel having a thickness of 70 nm has been formed across the entire surface of the semiconductor substrate 100 so as to cover the second gate electrode-forming film 106a made of a polysilicon film having a thickness of 100 nm and the first gate electrode-forming film 104b made of a polysilicon film having a thickness of 40 nm, thereby forming the FUSI gate electrode 115a of NiSi and the FUSI gate electrode 115b of Ni₃Si.

In contrast, in this variation, the full silicidation step is performed in a state where a metal film made of nickel having a thickness of 70 nm has been formed across the entire surface of the semiconductor substrate so as to cover a second gate electrode-forming film made of a polysilicon film having a thickness of 100 nm and a first gate electrode-forming film made of an SiGe film having a thickness of 40 nm.

Thus, it is possible to form a FUSI gate electrode of NiSi in the N-type MIS-forming region and a FUSI gate electrode of Ni₂(SiGe) or Ni₃(SiGe)₂ in the P-type MIS-forming region. It is possible to selectively form Ni₂(SiGe) or Ni₃(SiGe)₂ as the FUSI gate electrode in the P-type MIS-forming region by controlling the duration of the RTA process in the full silicidation step.

In the first variation, it is possible to obtain the FUSI gate electrode 115b made of Ni₂(SiGe) or Ni₃(SiGe)₂ by using an SiGe film instead of the first silicon film 104B in the first embodiment. Since the work function of a metal silicide film made of Ni₂(SiGe) or Ni₃(SiGe)₂ is larger than that of a metal silicide film made of Ni₃₁Si₁₂, Ni₃Si or Ni₂Si, it is possible to obtain a p-type MIS transistor having a lower threshold voltage than that of the p-type MIS transistor of the first embodiment. Thus, this variation is effective in realizing a p-type MIS transistor having a low threshold voltage with a high precision.

This variation may also employ a contact plug, as in the second embodiment, that is formed on the FUSI gate electrode in the N-type MIS-forming region and the FUSI gate electrode in the P-type MIS-forming region to extend across the L-shaped insulating film. Thus, it is possible to reliably ensure the electrical connection between the FUSI gate electrodes.

### Second Variation

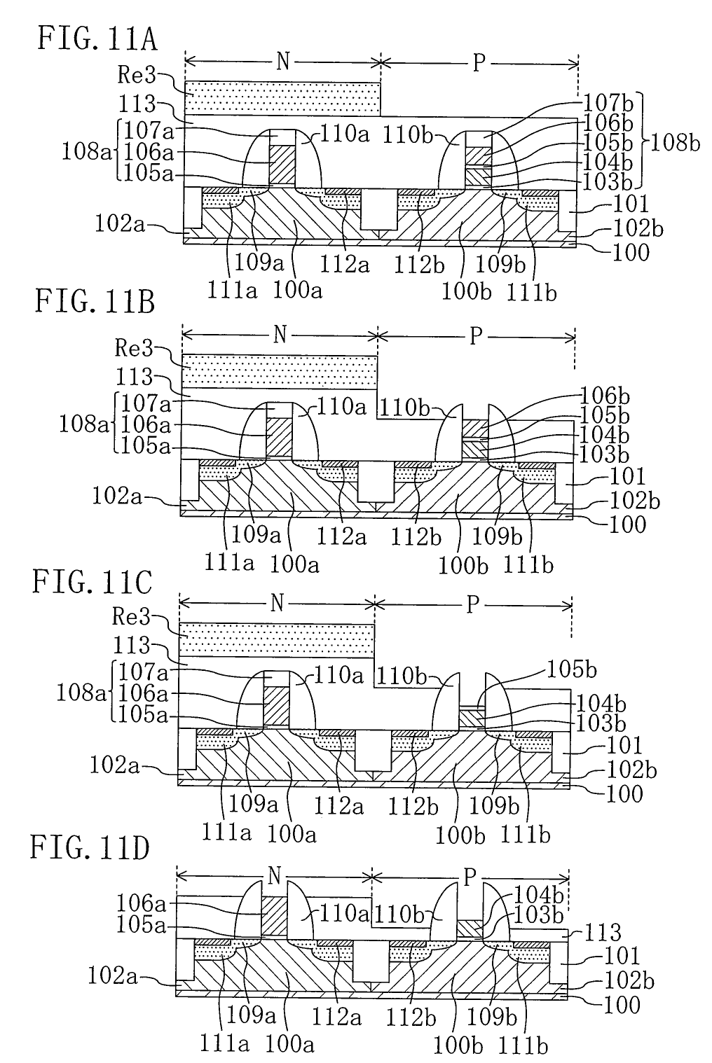

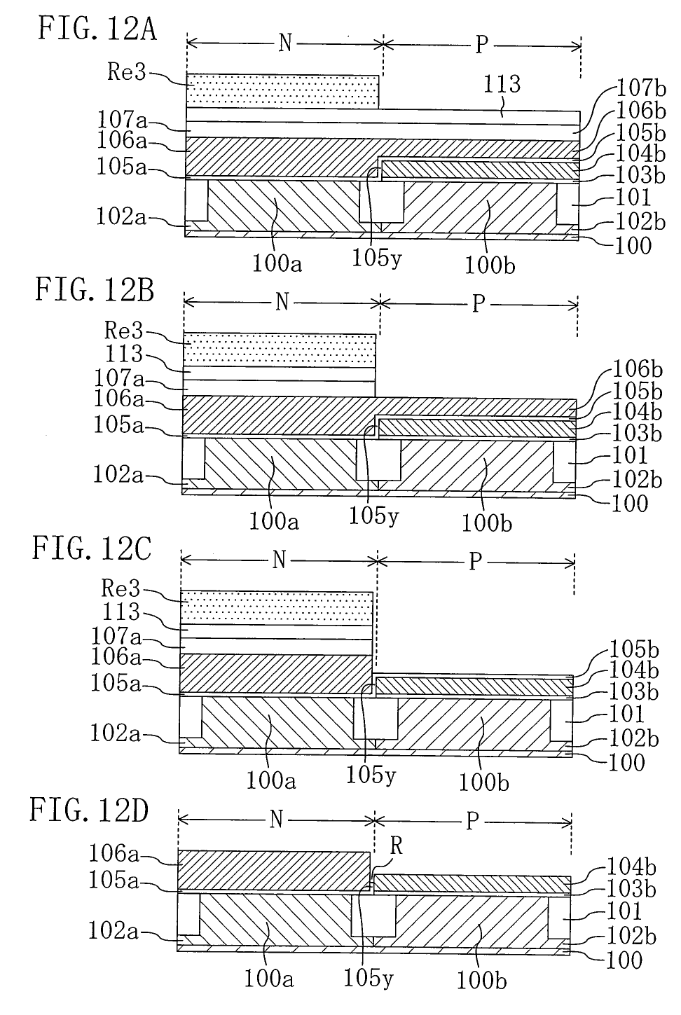

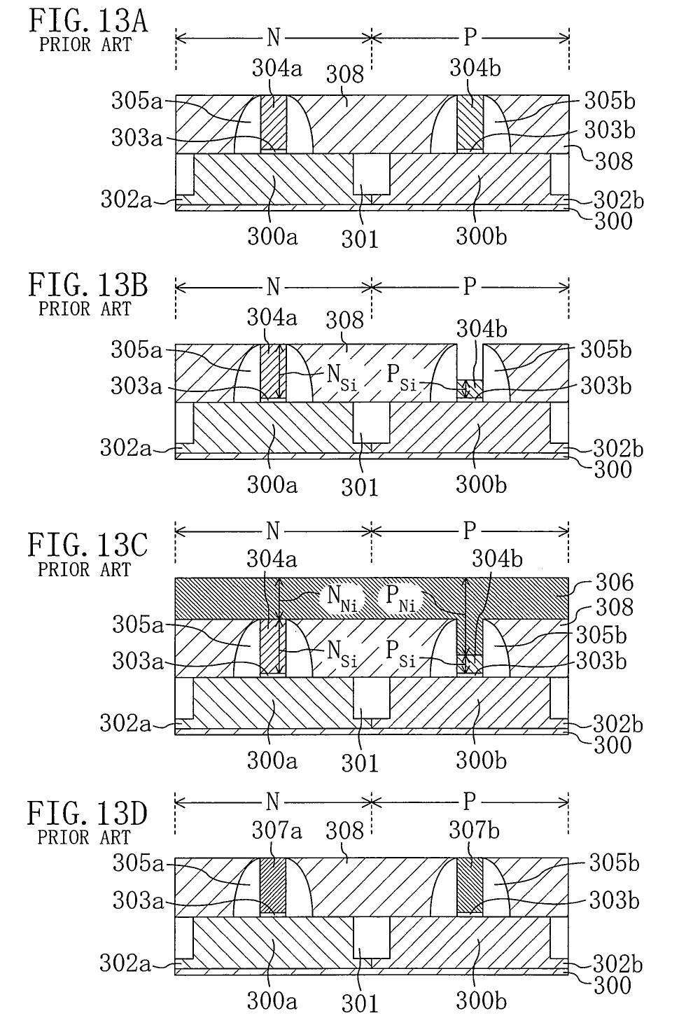

A method for manufacturing a semiconductor device according to a second variation of the present invention will now be described with reference to FIGS. 11A to 12D. FIGS. 11A to 11D are cross-sectional views taken in the gate length direction, sequentially showing important steps of the method for manufacturing a semiconductor device according to the second variation of the present invention. The N-type MIS-forming region and the P-type MIS-forming region are shown in these figures as being adjacent to each other for the sake of simplicity. The designation “N” in the left half of the figures denotes the N-type MIS-forming region, and the designation “P” in the right half of the figures denotes the P-type MIS-forming region. FIGS. 12A to 12D are cross-sectional views taken in the gate width direction, sequentially showing important steps of the method for manufacturing a semiconductor device according to the second variation of the present invention. The N-type MIS-forming region N is shown in the left half of the figures, and the P-type MIS-forming region P is shown in the right half of the figures.

The steps shown in FIGS. 11A to 11D correspond to the steps shown in FIGS. 12A to 12D, respectively. Therefore, the description below will follow the sequence of steps. In FIGS. 11A to 12D, like elements to those of the semiconductor device of the first embodiment above are denoted by like reference numerals. In the following description of this variation, what has already been described in the first embodiment will not be described redundantly.

First, steps shown in FIGS. 1A to 1D, FIGS. 2A and 4A, FIGS. 4B to 4D and FIG. 5A are performed successively.

Then, as shown in FIGS. 11A and 12A, a resist mask pattern Re3 is formed on the first interlayer insulating film 113.

Then, as shown in FIGS. 11B and 12B, an etching process is performed using the resist mask pattern Re3 as a mask so as to remove portions of the first interlayer insulating film 113, the second protection film 107a and the first protection film 107b that are exposed through the opening of the resist mask pattern Re3. Thus, as shown in FIG. 12B, a portion of the second gate electrode-forming film 106a of the second gate electrode pattern 108a that is present above the L-shaped insulating film 105y is exposed, and the silicon film 106b of the first gate electrode pattern 108b is exposed.

Then, as shown in FIGS. 11C and 12C, an etching process is performed using the resist mask pattern Re3 as a mask so as to remove a portion of the second gate electrode-forming film 106a of the second gate electrode pattern 108a that is present above the L-shaped insulating film 105y, thus exposing the upper surface of the L-shaped insulating film 105y, and to remove the silicon film 106b of the first gate electrode pattern 108b, thus exposing the upper surface of the etching stopper film 105b of the first gate electrode pattern 108b. In this process, the remaining portion of the second protection film 107a (more specifically, portions of the second protection film 107a of the second gate electrode pattern 108a other than the portion thereof that is present above the L-shaped insulating film 105y) can be used as an etching mask.

Then, as shown in FIGS. 11D and 12D, after the resist mask pattern Re3 is removed, an etching process is performed so as to remove the first interlayer insulating film 113, the remaining portion of the second protection film 107a, the L-shaped insulating film 105y and the etching stopper film 105b. Since the first interlayer insulating film 113, the second protection film 107a, the L-shaped insulating film 105y and the etching stopper film 105b are all silicon oxide films and have different etching characteristics from those of the gate electrode-forming films (polysilicon films) 106a and 104b, the gate electrode-forming films 106a and 104b are not removed in this process.

Then, steps shown in FIGS. 3A to 3C discussed above are successively performed.

Thus, a semiconductor device of the second variation is produced.

As in the first embodiment, the second variation does not use an MIS transistor whose thickness is adjusted by means of etching as with conventional methods as an n-type MIS transistor or as a p-type MIS transistor. Therefore, it is possible to realize with a high precision a fully-silicided gate electrode made of a metal silicide film of an intended silicide composition ratio both for the n-type MIS transistor and for the p-type MIS transistor, whereby it is possible to realize an intended threshold voltage with a high precision.

### Third Variation

A method for manufacturing a semiconductor device according to a third variation of the present invention will now be described. The following description will focus on differences between this variation and the first embodiment described above.

In the first embodiment, as shown in FIG. 5B, portions of the first interlayer insulating film 113 that are present above the upper surface of the second gate electrode-forming film 106a and the silicon film 106b, the second protection film 107a in the N-type MIS-forming region, and the first protection film 107b in the P-type MIS-forming region are removed by a dry or wet etching process, thereby exposing the upper surface of the second gate electrode-forming film 106a of the second gate electrode pattern 108a and the upper surface of the silicon film 106b of the first gate electrode pattern 108b.

In contrast, according to this variation, a surface flattening process is performed by a CMP method until the upper surface of the second gate electrode-forming film 106a of the second gate electrode pattern 108a and the upper surface of the silicon film 106b of the first gate electrode pattern 108b are exposed.

In such a case, a portion of the side wall 110a in the N-type MIS-forming region that is present above the upper surface of the second gate electrode-forming film 106a and a portion of the side wall 110b in the P-type MIS-forming region that is present above the upper surface of the silicon film 106b are polished and removed. However, this provides an advantageous effect of saving an etching step.

For the sake of simplicity, the first and second embodiments have been described with respect to a semiconductor device where there is one p-type MIS transistor PTr in the P-type MIS-forming region, but the present invention is not limited to this.

For example, effects similar to those of the first embodiment can be realized even with a semiconductor device where a plurality of p-type MIS transistors of different gate lengths coexist in the P-type MIS-forming region, since a p-type MIS transistor whose thickness is adjusted by means of etching as with conventional methods is not used as a p-type MIS transistor. In addition, it is possible to suppress variations in the silicide composition ratio of the metal silicide film between p-type MIS transistors of different gate lengths.

The first and second embodiments have been described above with respect to a case where the step of forming the second silicon film 106 is performed by a CVD method and a CMP method as shown in FIG. 1D, but the present invention is not limited to this. For example, the step of forming the second silicon film 106 may be performed only by a CVD method.

In such a case, the upper surface of the first gate electrode pattern 108b is higher than that of the second gate electrode pattern 108a, whereby the side wall 110b is higher than the side wall 110a. However, this provides an advantageous effect of saving a CMP step.

The first and second embodiments have been described above with respect to a case where the silicide films 112a and 112b are formed in upper portions of the source-drain regions 111a and 111b, respectively, and then the first interlayer insulating film 113 made of a silicon oxide film is formed across the entire surface of the semiconductor substrate 100 so as to cover the gate electrode patterns 108a and 108b, as shown in FIG. 4D, but the present invention is not limited to this.

For example, after the silicide films 112a and 112b are formed in upper portions of the source-drain regions 111a and 111b, respectively, a base insulating film made of a silicon nitride film may be formed across the entire surface of the semiconductor substrate 100 so as to cover the gate electrode patterns 108a and 108b, and then the first interlayer insulating film 113 may be formed on the base insulating film.

In such a case, in a subsequent step of forming contact holes, a first etching process is performed so as to form holes in the first interlayer insulating film 113 and the second interlayer insulating film 116 through which the upper surface of the base insulating film is exposed, and then a second etching process is performed so as to remove portions of the base insulating film that are exposed through the holes, thereby forming contact holes that are running through the base insulating film, the first interlayer insulating film 113 and the second interlayer insulating film 116 to reach the upper surface of the silicide films 112a and 112b. By employing such a 2-step etching process, it is possible to reduce the overetch of the silicide films 112a and 112b.

The first and second embodiments have been described above with respect to a case where the second gate insulating film 105a in the N-type MIS-forming region and the first gate insulating film 103b in the P-type MIS-forming region are of the same thickness (2 nm) and of the same material (a silicon oxide film), but the present invention is not limited to this.

For example, the second gate insulating film 105a and the first gate insulating film 103b may be of different materials, or the second gate insulating film 105a and the first gate insulating film 103b may be of different thicknesses.

Thus, it is possible to optimize the second gate insulating film 105a as a gate insulating film for an n-type MIS transistor and to optimize the first gate insulating film 103b as a gate insulating film for a p-type MIS transistor, whereby the design margin is increased.

For example, a high-k film may be used as a material of the second gate insulating film 105a in the N-type MIS-forming region and the first gate insulating film 103b in the P-type MIS-forming region. Particularly, it is preferred to use a high-k film whose relative dielectric constant is 10 or higher.

Then, the Fermi level pinning is eased, thereby improving the controllability of the threshold voltage for the n-type MIS transistor and for the p-type MIS transistor.

Specific examples of the high-k film include a high-k film made of a hafnium-type oxide such as hafnium oxide (HfO₂), hafnium silicate (HfSiO) and hafnium nitride silicate (HfSiON).

Other specific examples include a high-k film including at least one of a transition element, such as zirconium (Zr), titanium (Ti), tantalum (Ta), scandium (Sc) and yttrium (Y), aluminum (Al), and a rare-earth element such as a lanthanoid such as lanthanum (La).

In the first and second embodiments, a polysilicon film is used as the material of the second gate electrode-forming film 106a in the N-type MIS-forming region and the first gate electrode-forming film 104b in the P-type MIS-forming region. Alternatively, other semiconductor materials, including an amorphous silicon film or silicon, for example, may be used.

In the first and second embodiments, a metal film made of nickel is used as the metal film to be allowed to react with upper portions of the source-drain regions 111a and 111b in the step of forming the silicide films 112a and 112b. Alternatively, the metal film may be a metal film including at least one silicidation metal selected from the group including cobalt, titanium, tungsten, etc.

In the first and second embodiments, a metal film made of nickel is used as the metal film 114 to be allowed to react with the entirety of the gate electrode-forming films 106a and 104b in the step of forming the FUSI gate electrodes. Alternatively, the metal film may be a metal film including at least one FUSI metal selected from the group including a transition metal such as cobalt (Co), platinum (Pt), titanium (Ti), ruthenium (Ru) and iridium (Ir), and a lanthanoid such as ytterbium (Yb).

In the first and second embodiments, a silicon nitride film is used as a material of the side walls 110a and 110b. Alternatively, a layered film obtained by successively depositing a silicon oxide film and a silicon nitride film, for example, may be used.

As described above, the present invention is useful as a semiconductor device having a fully-silicided gate electrode and a method for manufacturing the same, as it is possible to realize a fully-silicided gate electrode made of a metal silicide film having an intended silicide composition ratio with a high precision.

What is claimed is:

1. A semiconductor device, comprising a first MIS transistor of a first conductivity type and a second MIS transistor of a second conductivity type, wherein:
the first MIS transistor includes:
a first gate insulating film formed in a first active region on a semiconductor substrate;
a first fully-silicided gate electrode formed on the first gate insulating film and made of a first metal silicide film; and
a first side wall formed on a side surface of the first fully-silicided gate electrode; and
the second MIS transistor includes:
a second gate insulating film in a second active region on the semiconductor substrate;
a second fully-silicided gate electrode formed on the second gate insulating film and made of a second metal silicide film whose silicide composition is different from that of the first metal silicide film; and
a second side wall formed on a side surface of the second fully-silicided gate electrode, wherein:
the semiconductor device further comprises an L-shaped insulating film having an L-shaped cross section, the L-shaped insulating film being integral with the second gate insulating film and extending from a top of an isolation region formed between the first active region and the second active region of the semiconductor substrate along a side surface of the second fully-silicided gate electrode in a gate width direction; and
the first fully-silicided gate electrode and the second fully-silicided gate electrode are electrically connected with each other.

2. The semiconductor device of claim 1, wherein:
an upper surface of the L-shaped insulating film is lower than that of the first fully-silicided gate electrode and that of the second fully-silicided gate electrode; and
the first fully-silicided gate electrode and the second fully-silicided gate electrode are in contact with each other above the L-shaped insulating film.

3. The semiconductor device of claim 1, further comprising a contact plug formed on the first fully-silicided gate electrode and the second fully-silicided gate electrode so as to extend across the L-shaped insulating film, the contact plug electrically connecting the first fully-silicided gate electrode and the second fully-silicided gate electrode with each other.

4. The semiconductor device of claim 1, wherein:
the first MIS transistor further includes:
a first extension region formed in a portion of the first active region which is under the side of the first fully-silicided gate electrode; and
a first source-drain region formed in a portion of the first active region which is under the side of the first side wall; and
the second MIS transistor further includes:
a second extension region formed in a portion of the second active region which is under the side of the second fully-silicided gate electrode; and
a second source-drain region formed in a portion of the second active region which is under the side of the second side wall.

5. The semiconductor device of claim 4, wherein:
the first MIS transistor further includes a first silicide film formed in an upper portion of the first source-drain region; and
the second MIS transistor further includes a second silicide film formed in an upper portion of the second source-drain region.

6. The semiconductor device of claim 1, wherein a height of an upper surface of the first fully-silicided gate electrode is different from that of an upper surface of the second fully-silicided gate electrode.

7. The semiconductor device of claim 1, wherein:
the first metal silicide film is made of Ni₃₁Si₁₂, Ni₃Si or Ni₂Si; and
the second metal silicide film is made of NiSi.

8. The semiconductor device of claim 1, wherein:
the first metal silicide film is made of Ni₂(SiGe) or Ni₃(SiGe)₂; and
the second metal silicide film is made of NiSi.

9. The semiconductor device of claim 1, wherein:
the first MIS transistor is a p-type MIS transistor; and
the second MIS transistor is an n-type MIS transistor.

10. The semiconductor device of claim 1, wherein the first gate insulating film and the second gate insulating film include a high-k film whose relative dielectric constant is 10 or higher.

11. The semiconductor device of claim 1, wherein the first gate insulating film and the second gate insulating film include a metal oxide.

12. The semiconductor device of claim 1, wherein the first gate insulating film and the second gate insulating film include at least one oxide selected from the group consisting of a hafnium-containing oxide, a tantalum-containing oxide, a lanthanum-containing oxide and an aluminum-containing oxide.

13. A method for manufacturing a semiconductor device including a first MIS transistor of a first conductivity type and a second MIS transistor of a second conductivity type, the method comprising:
a step (a) of forming a first active region and a second active region in a semiconductor substrate, the first active region and the second active region being isolated from each other by an isolation region;
a step (b) of successively forming a first insulating film and a first silicon film having a first thickness on the first active region;
a step (c), after the step (b), of successively forming a second insulating film and a second silicon film having a second thickness larger than the first thickness across the entire surface of the semiconductor substrate;
a step (d), after the step (c), of patterning the second silicon film, the second insulating film, the first silicon film and the first insulating film to thereby form on the first active region a first gate electrode pattern including a first gate insulating film made of the first insulating film and a first gate electrode-forming film made of the first silicon film, and patterning the second silicon film and the second insulating film to thereby form on the second active region a second gate electrode pattern including a second gate insulating film made of the second insulating film and a second gate electrode-forming film made of the second silicon film;
a step (e) of forming a first side wall on a side surface of the first gate electrode pattern and forming a second side wall on a side surface of the second gate electrode pattern;
a step (f), after the step (e), of successively removing the second silicon film and the second insulating film of the first gate electrode pattern to thereby expose the first gate electrode-forming film of the first gate electrode pattern;
a step (g), after the step (f), of forming a metal film on the first gate electrode-forming film of the first gate electrode pattern and the second gate electrode-forming film of the second gate electrode pattern; and
a step (h) of performing a heat treatment to allow an entirety of the first gate electrode-forming film of the first gate electrode pattern to react with the metal film so as to form a first fully-silicided gate electrode made of a first metal silicide film, and allow an entirety of the second gate electrode-forming film of the second gate electrode pattern to react with the metal film so as to form a second fully-silicided gate electrode made of a second metal silicide film having a silicide composition different from that of the first metal silicide film, wherein:
the step (c) includes a step of forming an L-shaped insulating film-forming film made of the second insulating film on the isolation region and on a side surface of the second silicon film;
the step (d) includes a step of patterning the L-shaped insulating film-forming film to thereby form an L-shaped insulating film on the isolation region and on a side surface of the second gate electrode-forming film; and
the first fully-silicided gate electrode of the first MIS transistor and the second fully-silicided gate electrode of the second MIS transistor are electrically connected with each other.

14. The method for manufacturing a semiconductor device of claim 13, wherein the step (f) includes a step (f1) of removing the second silicon film of the first gate electrode pattern to thereby expose the second insulating film of the first gate electrode pattern and removing a portion of the second gate electrode-forming film of the second gate electrode pattern that is present above the L-shaped insulating film to thereby expose the L-shaped insulating film, and a step (f2), after the step (f1), of removing the second insulating film of the first gate electrode pattern to thereby expose the first gate electrode-forming film of the first gate electrode pattern and removing a portion of the L-shaped insulating film that is present above an upper surface of the first gate electrode-forming film.

15. The method for manufacturing a semiconductor device of claim 14, wherein:
the step (f2) further includes a step of removing a portion of the L-shaped insulating film that is present between the first gate electrode-forming film and the second gate electrode-forming film so that an upper surface of the L-shaped insulating film is lower than that of the first gate electrode-forming film, thus forming a trench between the first gate electrode-forming film and the second gate electrode-forming film;
the step (g) includes a step of filling up the trench with the metal film; and
the step (h) includes a step of forming the first fully-silicided gate electrode and the second fully-silicided gate electrode so that the first fully-silicided gate electrode and the second fully-silicided gate electrode are in contact with each other above the L-shaped insulating film.

16. The method for manufacturing a semiconductor device of claim 13, further comprising a step (i), after the step (h), of forming a contact plug on the first fully-silicided gate electrode and the second fully-silicided gate electrode so as to extend across the L-shaped insulating film, the contact plug electrically connecting the first fully-silicided gate electrode and the second fully-silicided gate electrode with each other.

17. The method for manufacturing a semiconductor device of claim 13, further comprising:
a step (j), after the step (d) and before the step (e), of forming a first extension region in a portion of the first active region which is under the side of the first gate electrode pattern and forming a second extension region in a portion of the second active region which is under the side of the second gate electrode pattern;
a step (k), after the step (e) and before the step (f), of forming a first source-drain region in a portion of the first active region which is under the side of the first side wall and forming a second source-drain region in a portion of the second active region which is under the side of the second side wall.

18. The method for manufacturing a semiconductor device of claim 17, wherein:
the method further comprises a step (l), after the step (c) and before the step (d), of forming a protection film on the second silicon film;
the step (d) includes a step of patterning the protection film, the second silicon film, the second insulating film, the first silicon film and the first insulating film to thereby form on the first active region the first gate electrode pattern, which includes in an upper portion thereof a first protection film made of the protection film, and patterning the protection film, the second silicon film and the second insulating film to thereby form on the second active region the second gate electrode pattern, which includes in an upper portion thereof a second protection film made of the protection film,
the method further comprises a step (m), after the step (k) and before the step (f), of forming a first silicide film in an upper portion of the first source-drain region and a second silicide film in an upper portion of the second source-drain region; and
the step (f) further includes a step of removing the first protection film and the second protection film.

19. The method for manufacturing a semiconductor device of claim 18, wherein the step (f) includes:
a step (fa) of removing the first protection film of the first gate electrode pattern to expose the second silicon film of the first gate electrode pattern and removing the second protection film of the second gate electrode pattern to expose the second gate electrode-forming film of the second gate electrode pattern;
a step (fb), after the step (fa), of removing the second silicon film of the first gate electrode pattern to expose the second insulating film of the first gate electrode pattern and removing a portion of the second gate electrode-forming film of the second gate electrode pattern that is present above the L-shaped insulating film to expose the L-shaped insulating film; and
a step (fc), after the step (fb), of removing the second insulating film of the first gate electrode pattern to expose the first gate electrode-forming film of the first gate electrode pattern and removing a portion of the L-shaped insulating film that is present above an upper surface of the first gate electrode-forming film.

20. The method for manufacturing a semiconductor device of claim 19, wherein the step (fc) further includes a step of removing a portion of the L-shaped insulating film that is present between the first gate electrode-forming film and the second gate electrode-forming film.

21. The method for manufacturing a semiconductor device of claim 19, wherein the step (fa) is a step of removing the first protection film of the first gate electrode pattern and the second protection film of the second gate electrode pattern by means of etching.

22. The method for manufacturing a semiconductor device of claim 19, wherein the step (fa) is a step of removing the first protection film of the first gate electrode pattern and the second protection film of the second gate electrode pattern by a chemical mechanical polishing method.

23. The method for manufacturing a semiconductor device of claim 18, wherein the step (f) includes:
a step (fa) of removing the first protection film of the first gate electrode pattern to expose the second silicon film of the first gate electrode pattern and removing a portion of the second protection film of the second gate electrode pattern that is present above the L-shaped insulating film to expose a portion of the second gate electrode-forming film of the second gate electrode pattern that is present above the L-shaped insulating film;
a step (fb), after the step (fa), of removing the second silicon film of the first gate electrode pattern to expose the second insulating film of the first gate electrode pattern and removing a portion of the second gate electrode-forming film of the second gate electrode pattern that is present above the L-shaped insulating film to expose the L-shaped insulating film; and
a step (fc), after the step (fb), of removing the second insulating film of the first gate electrode pattern to expose the first gate electrode-forming film of the first gate electrode pattern and removing a portion of the second protection film of the second gate electrode pattern other than the portion thereof that is present above the L-shaped insulating film to expose the second gate electrode-forming film of the second gate electrode pattern,
wherein the step (fc) includes a step of removing a portion of the L-shaped insulating film that is present above an upper surface of the first gate electrode-forming film and then removing a portion of the L-shaped insulating film that is present between the first gate electrode-forming film and the second gate electrode-forming film.
